(19) United States
(12) Patent Application Publication
(10) Pub. No.: US 2025/0072140 A1
(43) Pub. Date: Feb. 27, 2025

(54) PHOTODETECTION DEVICE

(71) Applicant: SONY SEMICONDUCTOR SOLUTIONS CORPORATION, KANAGAWA (JP)

(72) Inventors: SHUHEI KASUKAWA, KANAGAWA (JP); MIZUKI NISHIDA, KANAGAWA (JP); AKIRA MATSUMOTO, KANAGAWA (JP); DAISUKE MURATA, KANAGAWA (JP)

(21) Appl. No.: 18/725,004

(22) PCT Filed: Jan. 7, 2022
(86) PCT No.: PCT/JP2022/000350

§ 371 Date: Jun. 27, 2024

(51) Int. Cl. H01L 27/146

(52) U.S. Cl. CPC H01L 27/14616; H01L 27/14607; H01L 27/1461; H01L 27/14627; H01L 27/14643

(57) ABSTRACT

A photodetection device according to one embodiment of the present disclosure includes: a semiconductor substrate having a first surface and a second surface that are opposed to each other and including a plurality of pixels arranged in an array in an in-plane direction; a first trench extending between the first surface and the second surface in an approximate middle of each of the plurality of pixels; a first semiconductor layer of a first conductivity type, the first semiconductor layer being provided in each of the plurality of pixels and extending between the first surface and the second surface; and a second semiconductor layer of a second conductivity type that is opposite to the first conductivity type, the second semiconductor layer being provided in each of the plurality of pixels and extending between the first surface and the second surface. When a reverse bias voltage is applied, a high electric field region is formed between the first semiconductor layer and the second semiconductor layer throughout between the first surface and the second surface.

### TECHNICAL FIELD

The present disclosure relates to a photodetection device.

### BACKGROUND ART

For example, PTL 1 discloses a photodetection device having a configuration in which, in a plurality of pixels arranged in a matrix, a first semiconductor layer of a first conductivity type is provided in an outer periphery portion adjacent to a boundary between pixels, a second semiconductor layer of a second conductivity type that is opposite to the first conductivity type is provided inside the first semiconductor layer in a plan view, and, when a reverse bias voltage is applied, a high electric field region including the first semiconductor layer and the second semiconductor layer is formed in a depth direction of a substrate.

### CITATION LIST

### Patent Literature

PTL 1: International Publication No. WO2019/098035

### SUMMARY OF THE INVENTION

Meanwhile, a photodetection device is requested to have improved jitter characteristics.

It is desirable to provide a photodetection device that enables improvement of jitter characteristics.

A photodetection device according to one embodiment of the present disclosure includes: a semiconductor substrate having a first surface and a second surface that are opposed to each other and including a plurality of pixels arranged in an array in an in-plane direction: a first trench extending between the first surface and the second surface in an approximate middle of each of the plurality of pixels; a first semiconductor layer of a first conductivity type, the first semiconductor layer being provided in each of the plurality of pixels and extending between the first surface and the second surface; and a second semiconductor layer of a second conductivity type that is opposite to the first conductivity type, the second semiconductor layer being provided in each of the plurality of pixels and extending between the first surface and the second surface. When a reverse bias voltage is applied, a high electric field region is formed between the first semiconductor layer and the second semiconductor layer throughout between the first surface and the second surface.

In the photodetection device according to one embodiment of the present disclosure, the first trench extending between the first surface and second surface of the semiconductor substrate is provided in the approximate middle of each of the plurality of pixels, and the first semiconductor layer of the first conductivity type and the second semiconductor layer of the second conductivity type that is opposite to the first conductivity type are provided in each of the plurality of pixels. The first semiconductor layer extends between the first surface and second surface of the semiconductor substrate. When a reverse bias voltage is applied, the high electric field region is formed between the first semiconductor layer and the second semiconductor layer throughout between the first surface and the second surface. This reduces variations in transfer time for transferring carriers generated by photoelectric conversion to the high electric field region in comparison with a typical photodetection device in which the high electric field region is formed in an in-plane direction of the semiconductor substrate.

### BRIEF DESCRIPTION OF DRAWING

FIG. 1 is a schematic cross-sectional diagram illustrating an example of a configuration of a main section of a photodetection device according to a first embodiment of the present disclosure.

FIG. 2 is a schematic diagram illustrating an example of a planar shape and layout of the photodetection device illustrated in FIG. 1.

FIG. 3 is a block diagram illustrating an example of a schematic configuration of the photodetection device illustrated in FIG. 1.

FIG. 4 is a diagram illustrating an example of an equivalent circuit diagram of a unit pixel of the photodetection device illustrated in FIG. 1.

FIG. 5 is a schematic cross-sectional diagram illustrating an example of an overall configuration of the photodetection device illustrated in FIG. 1.

FIG. 6A is a schematic cross-sectional view for describing an example of a method of manufacturing the photodetection device illustrated in FIG. 1.

FIG. 6B is a schematic cross-sectional diagram illustrating a process subsequent to FIG. 6A.

FIG. 6C is a schematic cross-sectional diagram illustrating a process subsequent to FIG. 6B.

FIG. 6D is a schematic cross-sectional diagram illustrating a process subsequent to FIG. 6C.

FIG. 6E is a schematic cross-sectional diagram illustrating a process subsequent to FIG. 6D.

FIG. 6F is a schematic cross-sectional diagram illustrating a process subsequent to FIG. 6E.

FIG. 6G is a schematic cross-sectional diagram illustrating a process subsequent to FIG. 6F.

FIG. 6H is a schematic cross-sectional diagram illustrating a process subsequent to FIG. 6G.

FIG. 6I is a schematic cross-sectional diagram illustrating a process subsequent to FIG. 6H.

FIG. J is a schematic cross-sectional diagram illustrating a process subsequent to FIG. 6I.

FIG. 7A is a chart illustrating distribution of impurities in a planar direction of a typical photodetection device.

FIG. 7B is a chart illustrating distribution of potentials in the planar direction of the typical photodetection device.

FIG. 8A is a chart illustrating distribution of impurities in the planar direction of the photodetection device illustrated in FIG. 1.

FIG. 8B is a chart illustrating distribution of potentials in the planar direction of the photodetection device illustrated in FIG. 1.

FIG. 9 is a schematic diagram illustrating an example of a planar shape and layout of a photodetection device according to a first modification example of the present disclosure.

FIG. 10 is a schematic diagram illustrating another example of the planar shape and layout of the photodetection device according to the first modification example of the present disclosure.

FIG. 11 is a schematic diagram illustrating another example of the planar shape and layout of the photodetection device according to the first modification example of the present disclosure.

FIG. 12 is a schematic cross-sectional diagram illustrating an example of a configuration of a main section of a photodetection device according to a second modification example of the present disclosure.

FIG. 13 is a schematic cross-sectional diagram illustrating an example of a configuration of a main section of a photodetection device according to a third modification example of the present disclosure.

FIG. 14 is a schematic cross-sectional diagram illustrating an example of a configuration of a main section of a photodetection device according to a fourth modification example of the present disclosure.

FIG. 15 is a schematic cross-sectional diagram illustrating an example of a configuration of a main section of a photodetection device according to a fifth modification example of the present disclosure.

FIG. 16 is a schematic cross-sectional diagram illustrating an example of a configuration of a main section of a photodetection device according to a sixth modification example of the present disclosure.

FIG. 17 is a schematic cross-sectional diagram illustrating an example of a configuration of a main section of a photodetection device according to a seventh modification example of the present disclosure.

FIG. 18 is a schematic cross-sectional diagram illustrating an example of a configuration of a main section of a photodetection device according to a second embodiment of the present disclosure.

FIG. 19 is a schematic cross-sectional diagram illustrating an example of a planar configuration of the photodetection device illustrated in FIG. 18.

FIG. 20A is a schematic cross-sectional view for describing an example of a method of manufacturing the photodetection device illustrated in FIG. 18.

FIG. 20B is a schematic cross-sectional diagram illustrating a process subsequent to FIG. 20A.

FIG. 20C is a schematic cross-sectional diagram illustrating a process subsequent to FIG. 20B.

FIG. 20D is a schematic cross-sectional diagram illustrating a process subsequent to FIG. 20C.

FIG. 20E is a schematic cross-sectional diagram illustrating a process subsequent to FIG. 20D.

FIG. 20F is a schematic cross-sectional diagram illustrating a process subsequent to FIG. 20E.

FIG. 20G is a schematic cross-sectional diagram illustrating a process subsequent to FIG. 20F.

FIG. 21A is a schematic cross-sectional view for describing another example of the method of manufacturing the photodetection device illustrated in FIG. 18.

FIG. 21B is a schematic cross-sectional diagram illustrating a process subsequent to FIG. 21A.

FIG. 21C is a schematic cross-sectional diagram illustrating a process subsequent to FIG. 21B.

FIG. 21D is a schematic cross-sectional diagram illustrating a process subsequent to FIG. 21C.

FIG. 21E is a schematic cross-sectional diagram illustrating a process subsequent to FIG. 21D.

FIG. 21F is a schematic cross-sectional diagram illustrating a process subsequent to FIG. 21E.

FIG. 22 is a schematic cross-sectional diagram illustrating an example of a configuration of a main section of a photodetection device according to an eighth modification example of the present disclosure.

FIG. 23 is a schematic diagram illustrating an example of a planar configuration of the photodetection device illustrated in FIG. 22.

FIG. 24 is a schematic diagram illustrating an example of a planar configuration of a photodetection device according to a ninth modification example of the present disclosure.

FIG. 25 is a schematic diagram illustrating an example of a planar configuration of a photodetection device according to a tenth modification example of the present disclosure.

FIG. 26 is a schematic diagram illustrating an example of a planar configuration of a photodetection device according to an eleventh modification example of the present disclosure.

FIG. 27 is a schematic diagram illustrating an example of a planar configuration of a photodetection device according to a twelfth modification example of the present disclosure.

FIG. 28 is a schematic diagram illustrating an example of a planar configuration of a photodetection device according to a thirteenth modification example of the present disclosure.

FIG. 29 is a schematic diagram illustrating an example of a planar configuration of a photodetection device according to a fourteenth modification example of the present disclosure.

FIG. 30 is a schematic cross-sectional diagram illustrating an example of a configuration of a main section of a photodetection device according to a fifteenth modification example of the present disclosure.

FIG. 31 is a schematic cross-sectional diagram illustrating an example of a configuration of a main section of a photodetection device according to a sixteenth modification example of the present disclosure.

FIG. 32 is a schematic cross-sectional diagram illustrating an example of a configuration of a main section of a photodetection device according to a seventeenth modification example of the present disclosure.

FIG. 33 is a cross-sectional diagram illustrating an example of a planar configuration of the photodetection device illustrated in FIG. 31.

FIG. 34 is a block diagram illustrating an example of an electronic apparatus using the photodetection device illustrated in FIG. 1 and the like.

FIG. 35 is a block diagram depicting an example of schematic configuration of a vehicle control system.

FIG. 36 is a diagram of assistance in explaining an example of installation positions of an outside-vehicle information detecting section and an imaging section.

### MODES FOR CARRYING OUT THE INVENTION

Some embodiments of the present disclosure will be described in detail below with reference to the drawings. Note that the following description is given of specific examples of the present disclosure, and the present disclosure is not limited to the following modes. In addition, the present disclosure is also not limited to the arrangement, dimensions, dimension ratios, and the like of components illustrated in each drawing. Note that the description will be given in the following order.
1. First Embodiment (a photodetection device in which respective trenches penetrating a semiconductor substrate are provided in a middle of a unit pixel and an outer periphery of the unit pixel and that includes a P-type semiconductor layer and an N-type semiconductor layer along side walls of the respective trenches)
   1-1. Configuration of Photodetection Device
   1-2. Method of Manufacturing Photodetection Device
   1-3. Workings and Effects
2. Modification Examples
   2-1. First Modification Example (an example of a planar shape and layout of the unit pixel)
   2-2. Second Modification Example (another example of a shape of a microlens)
   2-3. Third Modification Example (an example in which a low refractive index film is provided above a trench in the middle of the unit pixel)
   2-4. Fourth Modification Example (an example in which the N-type semiconductor layer is embedded in the trench in the middle of the unit pixel)
   2-5. Fifth Modification Example (an example in which a transparent electrode is embedded in the trench in the middle of the unit pixel)
   2-6. Sixth Modification Example (an example in which a bottom surface of the trench in the middle of the unit pixel is provided inside the semiconductor substrate)
   2-7. Seventh Modification Examples (an example in which an STI is provided on a surface side of the semiconductor substrate)
3. Second Embodiment (an example in which a trench penetrating the semiconductor substrate is provided at a position where the microlens has the smallest thickness and the P-type and N-type semiconductor layers are formed along a side wall of the trench)
   3-1. Configuration of Photodetection Device
   3-2. First Method of Manufacturing Photodetection Device
   3-3. Second Method of Manufacturing Photodetection Device
   3-4. Workings and Effects
4. Modification Examples
   4-1. Eighth Modification Example (an example in which P-type and N-type semiconductor layers are formed along a side wall of the trench provided in the outer periphery of the unit pixel)
   4-2. Ninth Modification Example (another example of a combination of planar layouts of the microlens and the unit pixel)
   4-3. Tenth Modification Example (another example of a combination of planar layouts of the microlens and the unit pixel)
   4-4. Eleventh Modification Example (another example of a combination of planar layouts of the microlens and the unit pixel)
   4-5. Twelfth Modification Example (another example of a combination of planar layouts of the microlens and the unit pixel)
   4-6. Thirteenth Modification Example (another example of a combination of planar layouts of the microlens and the unit pixel)
   4-7. Fourteenth Modification Example (another example of a combination of planar layouts of the microlens and the unit pixel)
   4-8. Fifteenth Modification Example (an example in which an impurity semiconductor layer extending in a planar direction is provided inside the semiconductor substrate)
   4-9. Sixteenth Modification Example (an example in which a plurality of trenches penetrating the semiconductor substrate is provided within the unit pixel)
   4-10. Seventeenth Modification Example (an example of a front-illuminated photodetection device)
5. Application Examples
6. Applications

### 1. First Embodiment

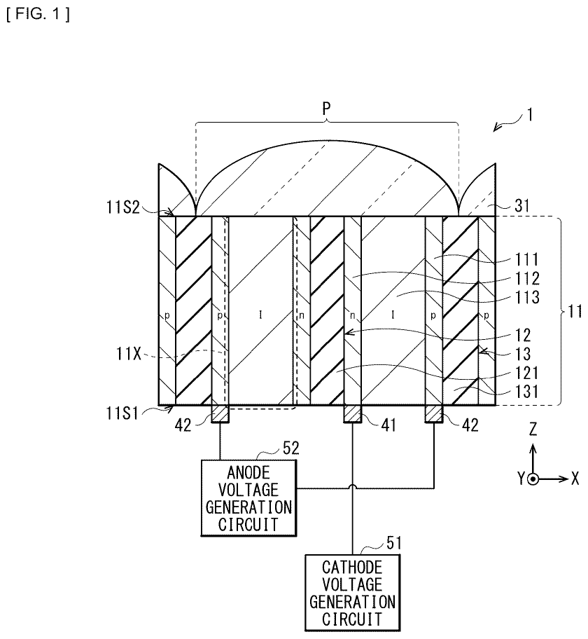

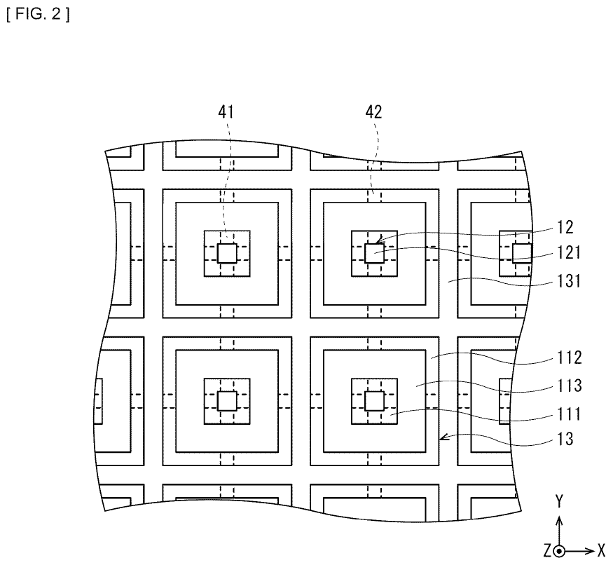

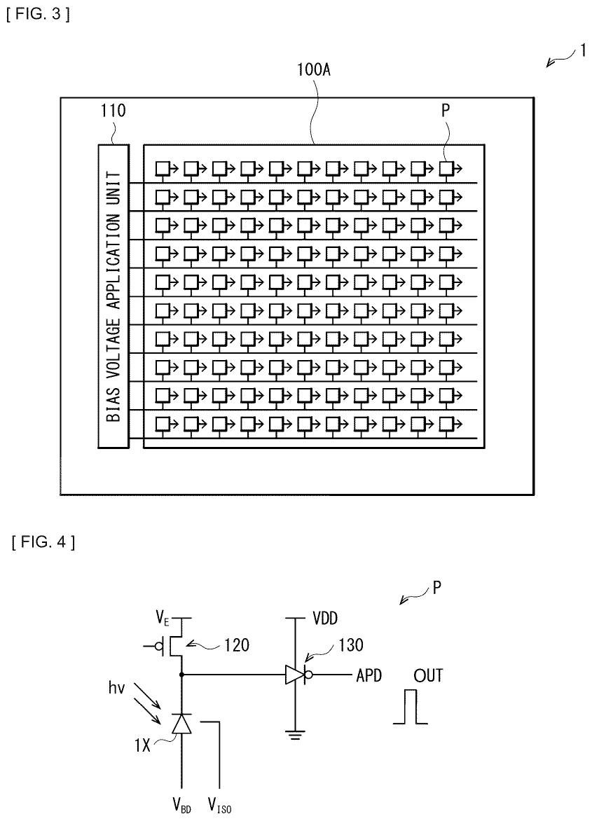

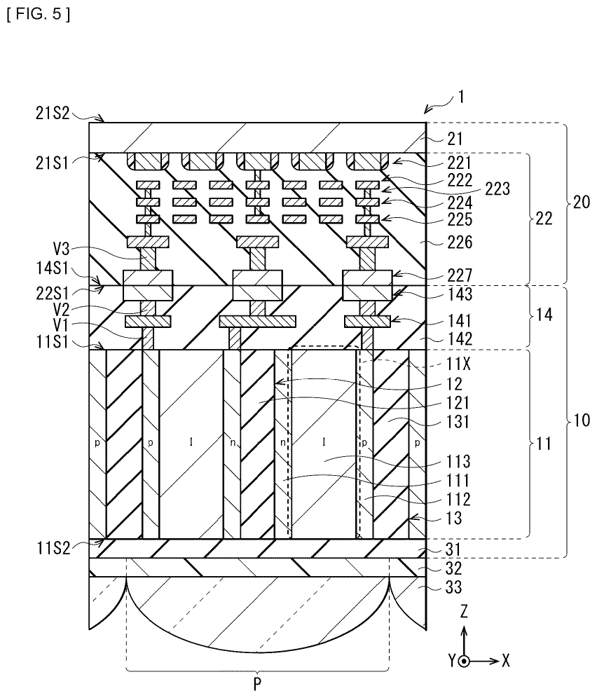

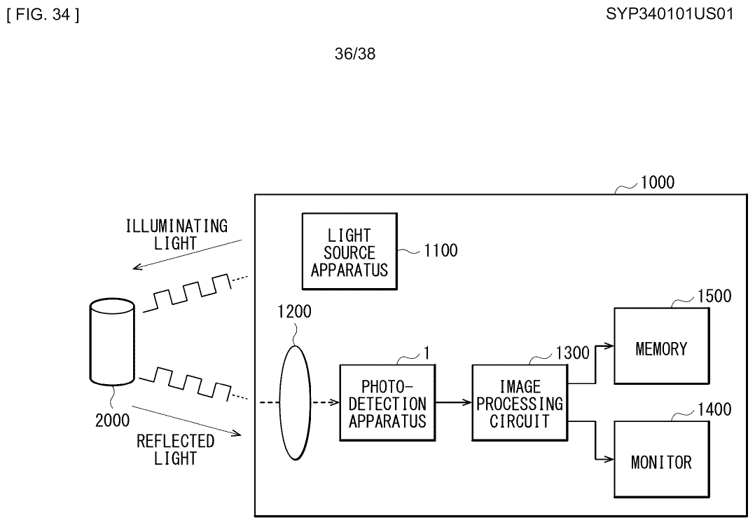

FIG. 1 is a schematic diagram illustrating an example of a configuration of a main section of a photodetection device (a photodetection device 1) according to a first embodiment of the present disclosure. FIG. 2 is a schematic diagram illustrating an example of a planar shape and layout of the photodetection device 1 illustrated in FIG. 1. FIG. 3 is a block diagram illustrating a schematic configuration of the photodetection device 1 illustrated in FIG. 1. FIG. 4 illustrates an example of an equivalent circuit diagram of a unit pixel P of the photodetection device 1 illustrated in FIG. 1. FIG. 5 schematically illustrates an example of a cross-sectional configuration of the photodetection device 1 including the main section illustrated in FIG. 1. The photodetection device 1 is applied to, for example, a distance image sensor (a distance image apparatus 1000, which will be described later with reference to FIG. 34) that measures a distance using a Time-of-Flight (ToF) method, an image sensor, and the like.

### (1-1. Configuration of Photodetection Device)

The photodetection device 1 includes, for example, a pixel array section 100A in which a plurality of unit pixels P is arranged in an array in row and column directions. The photodetection device 1 includes, as illustrated in FIG. 3, a bias voltage application unit 110 in addition to the pixel array section 100A. The bias voltage application unit 110 applies a bias voltage to each unit pixel P in the pixel array section 100A. In the present embodiment, a description will be given of a case of reading out electrons as a signal charge.

The unit pixel P includes, as illustrated in FIG. 4, a light-receiving element 1X, a quenching resistance element 120 including a p-type metal-oxide-semiconductor field-effect transistor (MOSFET), and an inverter 130 including, for example, a complementary MOSFET.

The light-receiving element 1X photoelectrically converts incident light to an electric signal and outputs the electric signal. Collaterally, the light-receiving element 1X photoelectrically converts incident light (photon) to the electric signal and outputs a pulse in response to incidence of the photon. The light-receiving element 1X is, for example, a single photon avalanche diode (SPAD) element. The SPAD element has characteristics that an avalanche multiplication region 11X (depletion layer) is formed by, for example, application of a reverse bias to between an anode and a cathode, and electrons generated in response to incidence of one photon are avalanche-multiplied to cause a large current to flow therein. In the light-receiving element 1X, for example, an anode thereof is coupled to the bias voltage application unit 110, and a cathode thereof is coupled to a source terminal of the quenching resistance element 120. A device voltage VB is applied by the bias voltage application unit 110 to the anode of the light-receiving element 1X.

The quenching resistance element 120 is coupled to the light-receiving element 1X in series, the source terminal thereof is coupled to the cathode of the light-receiving element 1X, and a drain terminal thereof is coupled to a power source, which is not illustrated. An excitation voltage V_{E} is applied from the power source to the drain terminal of the quenching resistance element 120. When a voltage generated by electrons avalanche-multiplied by the light-receiving element 1X reaches a negative voltage V_{BD}, the quenching resistance element 120 emits the electrons multiplied by the light-receiving element 1X and performs quenching to return the voltage to an initial voltage.

In the inverter 130, an input terminal thereof is connected with the cathode of the light-receiving element 1X and the source terminal of the quenching resistance element 120, and an output thermal thereof is connected with an calculation processing unit in a subsequent stage. The calculation processing unit is not illustrated. The inverter 130 outputs a light-receiving signal on the basis of carriers (signal charges) multiplied by the light-receiving element 1X. More specifically, the inverter 130 rectifies a voltage generated by the electrons multiplied by the light-receiving element 1X. The inverter 130 then outputs, to the calculation processing unit, a light-receiving signal (APD OUT) that forms, for example, a pulse waveform illustrated in FIG. 4 with an arrival time of one photon as a start point. For example, the calculation processing unit performs calculation processing to obtain a distance to an object on the basis of an occurrence timing of a pulse indicating the arrival time of one photon in each light-receiving signal, and obtains a distance on a unit pixel P-by-unit pixel P basis. On the basis of these distances, generated is a distance image in which distances to the object detected from the plurality of unit pixels P are planarly arranged.

The photodetection device 1 is, for example, a so-called back-illuminated photodetection device in which a logic substrate 20 is laminated on a surface (first surface 11S1) side of a semiconductor substrate 11 constituting a sensor substrate 10, and that receives light from a back surface side of the sensor substrate 10 (for example, a back surface (second surface 11S2) of the semiconductor substrate 11 constituting the sensor substrate 10).

In the photodetection device 1, as described above, the plurality of unit pixels P is arranged in the array in the row and column directions. In the semiconductor substrate 11, a first trench 12 penetrating between the first surface 11S1 and second surface 11S2 of the semiconductor substrate 11 is provided in an approximate middle of each of the plurality of unit pixels P arranged in the array. In the semiconductor substrate 11, a second trench 13 is further provided around the unit pixel P. The second trench 13 penetrates between the first surface 11S1 and second surface 11S2 of the semiconductor substrate 11 similarly to the first trench 12, and electrically separates adjacent unit pixel P. In the present embodiment, a P-type semiconductor layer 111 is provided along a side wall of the second trench 13, an N-type semiconductor layer 112 is provided along a side wall of the first trench 12, and a high electric field region in which avalanche multiplication occurs when a reverse bias voltage that is higher than a breakdown voltage is applied (the avalanche multiplication region 11X) is formed between the P-type semiconductor layer 111 and the N-type semiconductor layer 112 throughout between the first surface 11S1 and the second surface 11S2.

Note that “p” and “n” in the drawing respectively represent the P-type semiconductor layer and the N-type semiconductor layer. Furthermore, “+” after “p” represents an impurity concentration in the P-type semiconductor layer. Similarly, “+” after “n” represents an impurity concentration in the N-type semiconductor layer. Here, the larger the number of “+”, the higher the impurity concentration. Similar things apply to the subsequent drawings.

The sensor substrate 10 includes, for example, the semiconductor substrate 11 and a multilayer wiring layer 19. The semiconductor substrate 11 includes a silicon substrate. The semiconductor substrate 11 has the first surface 11S1 and the second surface 11S2 that are opposed to each other. In the semiconductor substrate 11, as described above, the N-type semiconductor layer 112 in which, for example, an impurity concentration is controlled to be an n-type is provided along the side wall of the first trench 12, and the P-type semiconductor layer 111 is provided along the side wall of the second trench 13, on the unit pixel P-by-unit pixel P basis. In the semiconductor substrate 11, an I-type semiconductor layer 113 is provided between the P-type semiconductor layer 111 and the N-type semiconductor layer 112.

The light-receiving element 1X includes a multiplication region in which carriers are avalanche-multiplied by the high electric field region (avalanche multiplication region 11X), and is, for example, a SPAD element that forms the avalanche multiplication region 11X by application of a high negative voltage to the cathode 41 and that enables avalanche multiplication of electrons generated by incidence of one photon.

In the light-receiving element 1X, the avalanche multiplication region 11X is formed in the I-type semiconductor layer 113 between the P-type semiconductor layer 111 and the N-type semiconductor layer 112. The avalanche multiplication region 11X is the high electric field region (depletion layer) formed between the P-type semiconductor layer 111 and the N-type semiconductor layer 112 by application of a reverse bias voltage that is higher than a breakdown voltage to the cathode and the anode. In the avalanche multiplication region 11X, electrons (e−) generated by one photon incident on the light-receiving element 1X are multiplied.

On the first surface 11S1 of the semiconductor substrate 11, an electrode 41 serving as the cathode at the time of application of the reverse bias (hereinafter referred to as a cathode 41) is ohmic-coupled at one or more locations on the N-type semiconductor layer 112 (refer to, for example, FIG. 2). Additionally, on the first surface 11S1 of the semiconductor substrate 11, an electrode 42 serving as the anode at the time of application of the reverse bias (hereinafter referred to as an anode 42) is ohmic-coupled at one or more locations on the P-type semiconductor layer 111 (refer to, for example, FIG. 2). A cathode voltage generation circuit 51 and an anode voltage generation circuit 52 are respectively coupled to the cathode 41 and the anode 42.

For example, an oxide film 121 having an insulation property such as a film of silicon oxide (SiO2) is embedded in the first trench 12 extending between the first surface 11S1 and second surface 11S2 of the semiconductor substrate 11 and penetrating the semiconductor substrate 11.

Similarly to the first trench 12, the second trench 13 extending between the first surface 11S1 and second surface 11S2 of the semiconductor substrate 11 and penetrating the semiconductor substrate 11 electrically separates adjacent unit pixels P, and is provided, for example, in a grid-like shape in the pixel array section 100A so as to surround each of the plurality of unit pixels P in a plan view. Similarly to the first trench 12, an oxide film 131 having an insulation property, such as silicon oxide (SiO₂), is embedded in the second trench 13.

A multilayer wiring layer 14 is provided on the first surface 11S1 side of the semiconductor substrate 11. In the multilayer wiring layer 14, a wiring layer 141 including one or more wires is formed in an interlayer insulation layer 142. The wiring layer 141 is used to, for example, supply a voltage to be applied to the semiconductor substrate 11 and the light-receiving element 1X and extract carriers generated in the light-receiving element 1X. A portion of the wiring in the wiring layer 141 is electrically coupled to the P-type semiconductor layer 111 or the N-type semiconductor layer 112 via a via V1. A plurality of pad electrodes 143 is embedded in a surface of the interlayer insulation layer 142 (a surface 14S1 of the multilayer wiring layer 14) on the opposite side of the semiconductor substrate 11 side. The plurality of pad electrodes 143 is electrically coupled to a portion of the wiring in the wiring layer 141 via a via V2. Note that FIG. 1 illustrates the example in which one wiring layer 141 is formed in the multilayer wiring layer 14, but a total number of wiring layers in the multilayer wiring layer 14 is not limited, and two or more wiring layers may be formed.

The interlayer insulation layer 142 includes, for example, a single layer film containing one kind of silicon oxide (SiOₓ), tetraethylorthosilicate (TEOS), silicon nitride (SiNₓ), and silicon oxynitride (SiOₓN_{y}), or a laminated film containing two or more kinds of silicon oxide (SiOₓ), TEOS, silicon nitride (SiNₓ), and silicon oxynitride (SiOₓN_{y}).

The wiring layer 141 is formed using, for example, aluminum (Al), copper (Cu), tungsten (W), or the like.

The pad electrode 143 is exposed to a bonding surface that is bonded with the logic substrate 20 (the surface 14S1 of the multilayer wiring layer 14), and is used for, for example, coupling to the logic substrate 20. The pad electrode 143 is formed using, for example, copper (Cu).

The logic substrate 20 includes, for example, a semiconductor substrate 21 and a multilayer wiring layer 22. The semiconductor substrate 21 includes a silicon substrate. The logic substrate 20 includes, for example, the cathode voltage generation circuit 51, the anode voltage generation circuit 52, the bias voltage application unit 110, which are described above, a readout circuit, and a logic circuit. The bias voltage application unit 110 includes modulation voltage generation circuits 53A and 53B. The readout circuit outputs an image signal based on a charge output from the unit pixel P in the pixel array section 100A. The logic circuit includes a vertical driving circuit, a column signal processing circuit, a horizontal driving circuit, an output circuit, and the like.

In the multilayer wiring layer 22, for example, gate wiring 221 of a transistor constituting the readout circuit, wiring layers 222, 223, 224, and 225 each including one or more wires are sequentially laminated from the semiconductor substrate 21 side with an interlayer insulation layer 226 interposed therebetween. A plurality of pad electrodes 227 is embedded in a surface of the interlayer insulation layer 226 (a surface 22S1 of the multilayer wiring layer 22) on the opposite side of the semiconductor substrate 21 side. The plurality of pad electrodes 227 is electrically coupled to a portion of the wiring in the wiring layer 225 via a via V3.

Similarly to the interlayer insulation layer 142, an interlayer insulation layer 117 includes, for example, a single layer film containing one kind of silicon oxide (SiOₓ), TEOS, silicon nitride (SiNₓ) and silicon oxynitride (SiOₓN_{y}), or a laminated film containing two or more kinds of silicon oxide (SiOₓ), TEOS, silicon nitride (SiNₓ) and silicon oxynitride (SiOₓN_{y}).

The gate wiring 221 and the wiring layers 222, 223, 224, and 225 are formed using, for example, aluminum (Al), copper (Cu), tungsten (W), or the like, similarly to the wiring layer 141.

The pad electrode 227 is exposed to a bonding surface that is bonded with the sensor substrate 10 (the surface 22S1 of the multilayer wiring layer 22), and is used for, for example, coupling to the sensor substrate 10. The pad electrode 227 is formed using, for example, copper (Cu), similarly to the pad electrode 143.

In the photodetection device 1, for example, Cu—Cu bonding is performed between the pad electrode 143 and the pad electrode 227. With this configuration, the cathode of the light-receiving element 1X is electrically coupled to the quenching resistance element 120 provided on the logic substrate 20 side, and the anode of the light-receiving element 1X is electrically coupled to the bias voltage application unit 110.

For example, a microlens 31 is provided on the light-receiving surface (second surface 11S2) side of the semiconductor substrate 11 on the unit pixel P-by-unit pixel P basis. A protective layer 32 and a color filter 33 may be further provided between the second surface 11S2 of the semiconductor substrate 11 and the microlens 31.

The microlens 31 condenses light incident from above the microlens 31 into the light-receiving element 1X, and is formed using, for example, oxide silicon (SiOₓ) or the like.

### (1-2. Method of Manufacturing Photodetection Device)

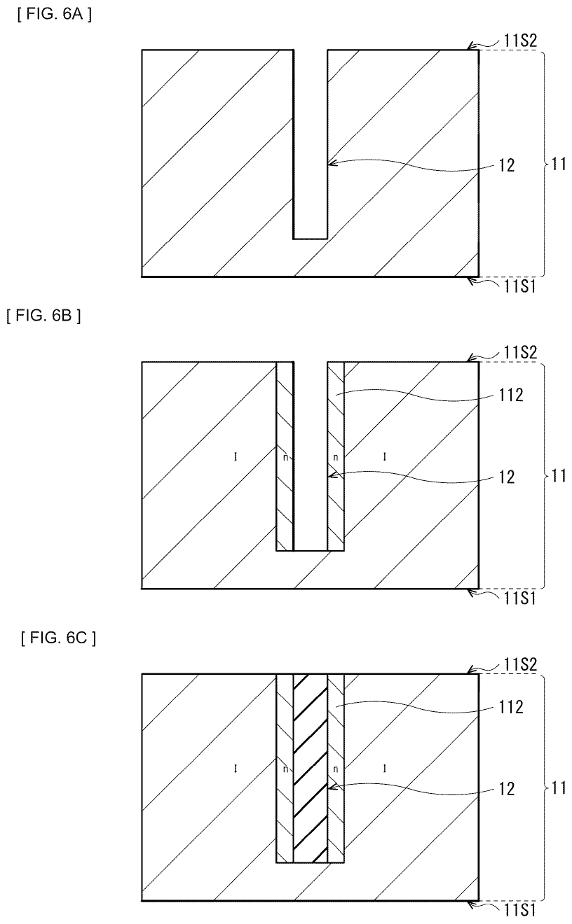

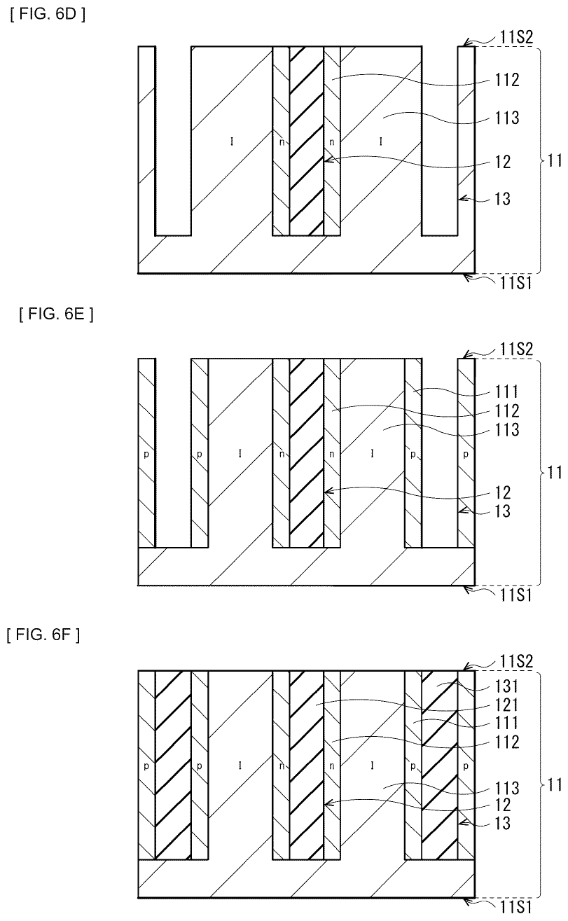

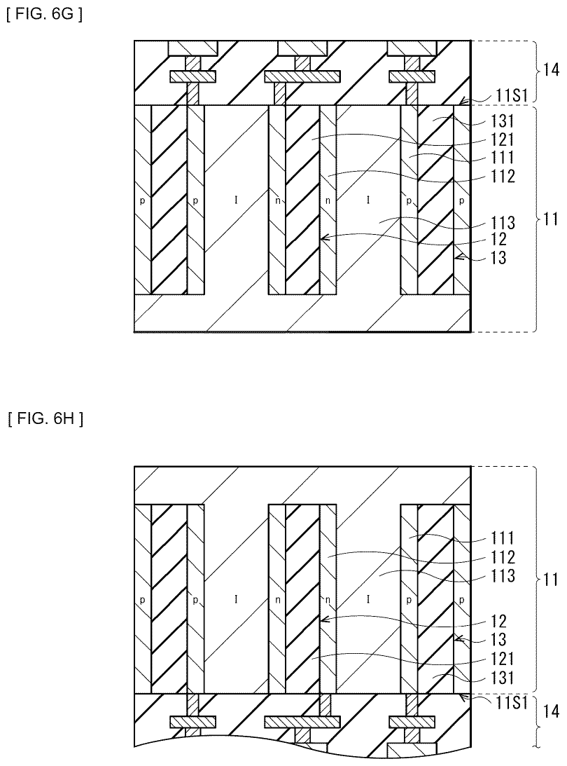

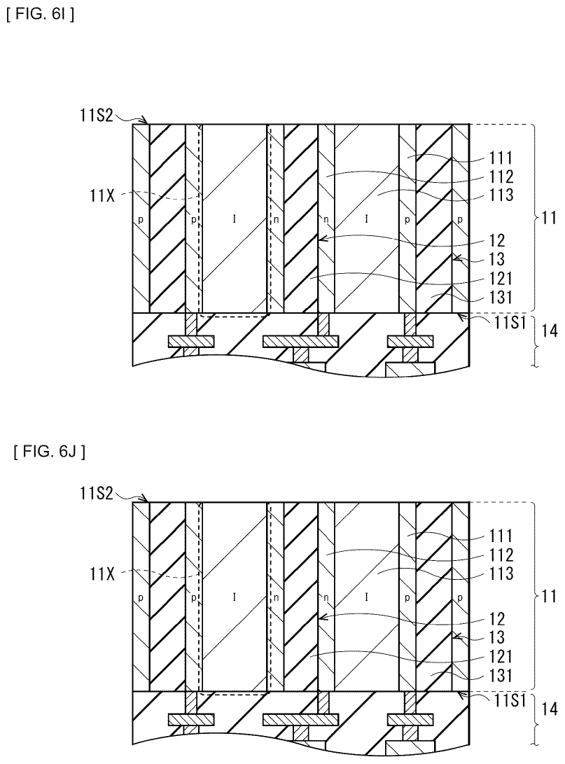

For example, it is possible to manufacture the sensor substrate 10 as follows. First, as illustrated in FIG. 6A, the first trench 12 having a predetermined depth from the second surface 11S2 side of the semiconductor substrate 11 is formed. Subsequently, as illustrated in FIG. 6B, a side wall of the first trench 12 is doped with highly concentrated n-type impurities using, for example, solid-phase diffusion, to form the N-type semiconductor layer 112.

Subsequently, as illustrated in FIG. 6C, the first trench 12 is embedded using, for example, polysilicon. Subsequently, as illustrated in FIG. 6D, the second trench 13 having a predetermined depth from the second surface 11S2 side of the semiconductor substrate 11 is formed. Subsequently, as illustrated in FIG. 6E, a side wall of the second trench 13 is doped with highly concentrated p-type impurities using, for example, solid-phase diffusion, to form the P-type semiconductor layer 111.

Subsequently, as illustrated in FIG. 6F, the second trench 13 is embedded using, for example, polysilicon. Subsequently, the second surface 11S2 of the semiconductor substrate 11 is polished by chemical mechanical planarization (CMP) to be planarized, and thereafter the multilayer wiring layer 14 is formed as illustrated in FIG. 6G. Thereafter, as illustrated in FIG. 6H, the semiconductor substrate 11 is inversed, and the logic substrate 20, which is separately produced, is attached to the semiconductor substrate 11. At this time, Cu—Cu bonding is performed between a plurality of pad electrodes 193 exposed on a bonding surface (surface 19S1) of the multilayer wiring layer 19 and a plurality of pad sections 217 exposed on a bonding surface (surface 22S) of the multilayer wiring layer 22 on the logic substrate 20 side.

Subsequently, as illustrated in FIG. 6I, for example, the first surface 11S1 of the semiconductor substrate 11 is polished by, for example, a grinder, CMP, or LEP, to expose a bottom surface of the first trench 12 and a bottom surface of the second trench 13, and planarize the first surface 11S1. Subsequently, polysilicon embedded in the first trench 12 and the second trench 13 is removed, and thereafter the oxide films 121 and 131 containing SiO₂ or the like are respectively embedded in the first trench 12 and the second trench 13 again, as illustrated in FIG. 6J. Thereafter, the first surface 11S1 of the semiconductor substrate 11 is planarized by, for example, CMP, and thereafter the microlens 31 and the like are formed. Accordingly, the photodetection device 1 illustrated in FIGS. 1 and 5 is completed.

### (1-3. Workings and Effects)

In the photodetection device 1 according to the present embodiment, the first trench 12 extending between the first surface 11S1 and second surface 11S2 of the semiconductor substrate 11 and penetrating the first surface 11S1 and second surface 11S2 of the semiconductor substrate 11 is provided in an approximate middle of each of the plurality of unit pixels P, the second trench 13 extending between the first surface 11S1 and second surface 11S2 of the semiconductor substrate 11 and penetrating the first surface 11S1 and second surface 11S2 of the semiconductor substrate 11 is provided around each unit pixel P, the N-type semiconductor layer 112 is provided along the side wall of the first trench 12, and the P-type semiconductor layer 111 is provided along the side wall of the second trench 13. When a reverse bias voltage is applied, the high electric field region (avalanche multiplication region 11X) is formed between the P-type semiconductor layer 111 and the N-type semiconductor layer 112 throughout between the first surface 11S1 and the second surface 11S. A description about this will be given below.

In a technique of SPAD, a high bias voltage is applied to multiply carriers generated by photoelectric conversion of incident light, whereby it is possible to extract the multiplied carriers as a large signal. In a typical SPAD element, for example, a P-type semiconductor layer and a P-type constituting an avalanche multiplication region are laminated adjacent to a surface of a semiconductor substrate on the opposite side of a light-receiving surface in a thickness direction of the semiconductor substrate. However, such a SPAD element has an issue that a volume of the avalanche multiplication region with respect to a pixel is small and single photon detection efficiency (PED) is low.

In addition, one of characteristics that the SPAD element is requested to have is jitter. The jitter generally represents fluctuations in timing of a digital signal. In the SPAD element, the jitter represents fluctuations in timing of a detection signal that has undergone reception of light, photoelectric conversion, multiplication, and detection. Since photoelectric conversion using detected light occurs in the whole pixel, there occurs a difference in time taken to transfer electrons to the avalanche multiplication region in which a high electric field is provided depending on generation positions of carriers (for example, electrons) generated by photoelectric conversion. For example, in a back-illuminated SPAD structure, the closer a carrier to a light-receiving surface side, the longer transfer time taken to transfer the carrier to the multiplication region. A difference in the transfer time appears as jitter characteristics.

Furthermore, for example, in a back-illuminated SPAD element, a pair of anode and cathode electrodes is, for example, provided in parallel on a front surface side of the semiconductor substrate. In the SPAD element having the above-mentioned structure, to suppress edge breakdown between the avalanche multiplication region and the electrode provided in an outer periphery of a pixel, it is requested to suppress an electric field by increasing a distance between the anode and the cathode, but it becomes difficult to achieve compatibility with miniaturization.

Furthermore, in the SPAD element having the above-mentioned structure, when a reverse bias voltage is applied, a depletion layer tends to extend toward a bulk portion, whereby variations in breakdown voltage are likely to occur.

Additionally, as described above, in the photodetection device having a configuration in which a first semiconductor layer of a first conductivity type is provided in an outer periphery portion near a boundary between pixels, a second semiconductor layer of a second conductivity type that is opposite to the first conductivity type is provided inside the first semiconductor layer in a plan view, and a high electric field region including the first semiconductor layer and the second semiconductor layer is formed in a depth direction of a substrate when a reverse bias voltage is applied, there is a possibility that the following issues occur.

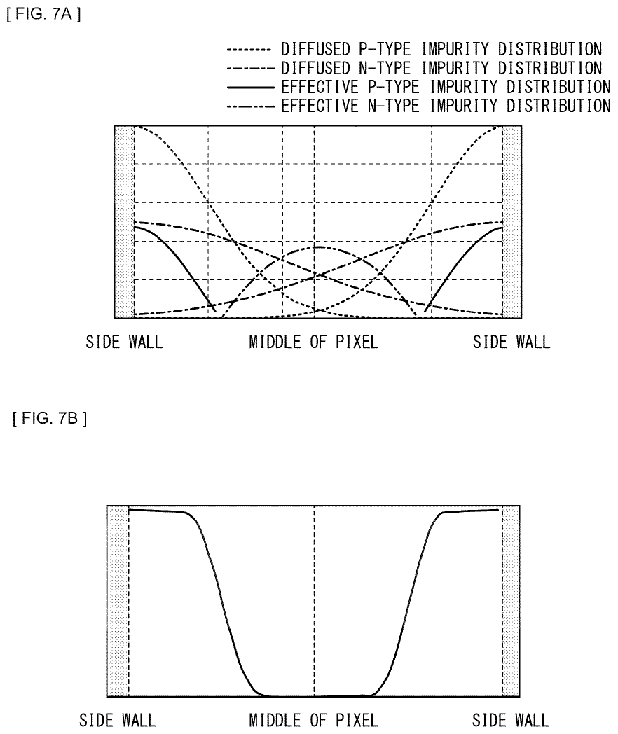

For example, in a case where a P-N junction is formed using ion implantation, it is difficult to uniformly distribute impurities in the depth direction. Additionally, in a case where the P-N junction is formed using ion implantation using solid-phase diffusion, for example, since a base portion of distribution of impurities introduced by solid-phase diffusion forms an N-type region in the middle of a pixel as illustrated in FIG. 7A, it is difficult to obtain a high concentration. In a case where P-N junctions distributed in the depth direction are formed with non-uniform impurity distribution, high electric fields generated in the P-N junctions also become non-uniform, whereby the PDE decreases.

Additionally, in the case where the P-N junctions are formed with low concentrated impurity distribution, the depletion layer is easily extended by application of a reverse bias, and variations in breakdown voltage easily occur. Additionally, in a case where a concentration in a P/N-type region is low, since locally highly concentrated impurity distribution is formed due to ohmic coupling with the anode electrode, the cathode electrode, and the like, there is a possibility that edge breakdown deteriorates when a distance between the electrodes becomes shorter with the miniaturization of a pixel.

Furthermore, in a case where the multiplication region is formed by the P-N junctions, potential distribution as illustrated in FIG. 7B is formed in a cross-sectional direction of the pixel. In the illustrated potential distribution, since it takes time for a photoelectron to be induced to the avalanche multiplication region, there is a possibility that the jitter characteristics deteriorate.

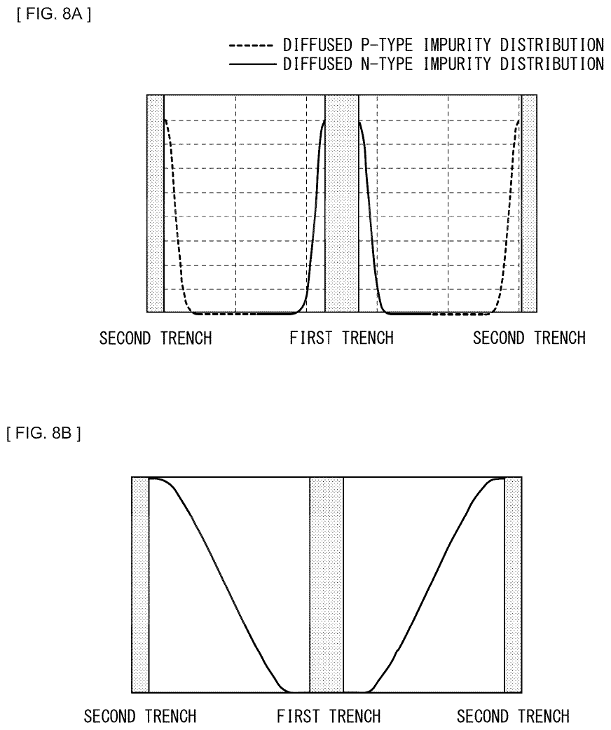

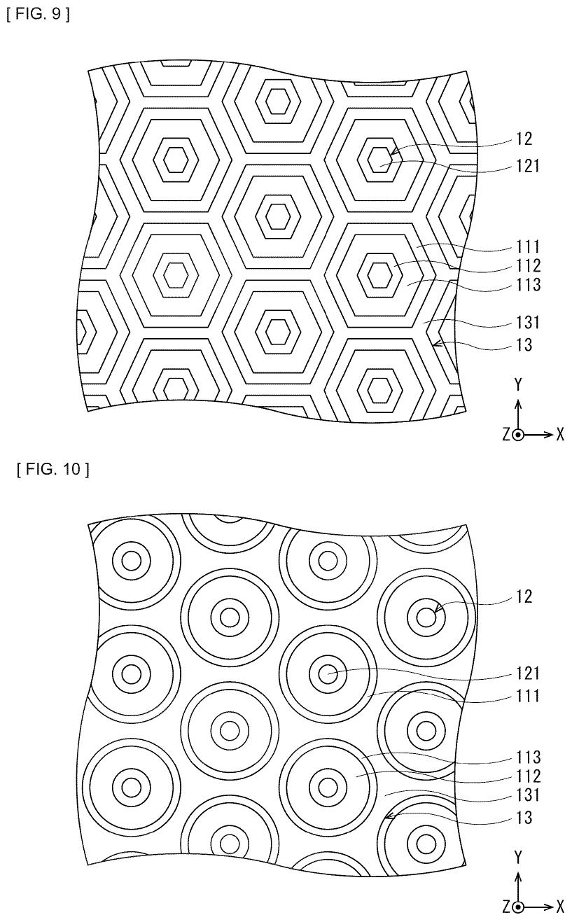

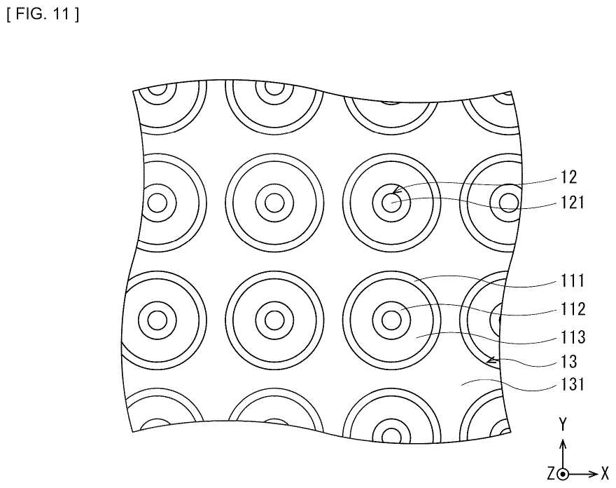

To address this, in the present embodiment, the first trench 12 and the second trench 13 penetrating the semiconductor substrate 11 are respectively provided in the approximate middle of each of the plurality of unit pixels P and around each of the plurality of unit pixels P, n-type impurities and p-type impurities are distributed in the respective side walls of the first trench 12 and the second trench 13 using conformal doping by solid-phase diffusion, and the N-type semiconductor layer 112 and the P-type semiconductor layer 111 are provided. As a result, P-I-N-type impurity distribution as illustrated in FIG. 8A is formed between the first trench 12 and the first trench 12. At this time, by applying a reverse bias voltage to between the first trench 12 and the second trench 13, steep potential distribution is formed throughout between the first trench 12 and the second trench 13 as illustrated in FIG. 8B.

This allows the photodetection device 1 according to the present embodiment to improve the jitter characteristics.

Additionally, in the photodetection device 1 according to the present embodiment, since the steep potential distribution is formed throughout between the first trench 12 and the second trench 13 as illustrated in FIG. 8B, it is possible to improve the PDE.

Furthermore, in the photodetection device 1 according to the present embodiment, the first trench 12 and the second trench 13 are doped with impurities using solid-phase diffusion, it is possible to form highly concentrated impurity distribution. Thus, since implantation for ohmic coupling between the anode and the cathode becomes unnecessary, the occurrence of edge breakdown is reduced. Additionally, the shorter the distance between the first trench 12 and the second trench 13, the lower a breakdown voltage necessary for multiplication. Thus, it is advantageous for miniaturization of a pixel.

Furthermore, in the photodetection device 1 according to the present embodiment, since there is no room for expansion of the depletion layer between the first trench 12 and the second trench 13, it is possible to reduce variations in breakdown voltage between unit pixels P.

Subsequently, the first embodiment, first to seventeenth modification examples, application examples, and applications will be described. In the following description, a component that is similar to that in the first embodiment is denoted by an identical reference sign, and a description thereof is omitted.

### 2. Modification Examples

### 2-1. First Modification

In the above-mentioned first embodiment, the description has been given of the example in which the unit pixels P each having a substantially square shape are arranged in a matrix, but a planar shape and layout of the unit pixels P are not limited thereto.

FIG. 9 is a schematic diagram illustrating an example of a planar shape and layout of the photodetection device 1 according to a first modification of the present disclosure. The unit pixels P may each have, for example, a substantially regular hexagonal shape as a planar shape as illustrated in FIG. 9, and may be arranged in a honeycomb structure. Accordingly, it is possible to enhance field uniformity in the high electric field region while maximizing the area of the unit pixels P. Therefore, in addition to the effects brought by the above-mentioned first embodiment, it is possible to further increase the PDE.

FIGS. 10 and 11 each schematically illustrating another example of the planar shape and layout of the photodetection device 1 according to the first modification example of the present disclosure. The unit pixels P may each have, for example, a substantially circular shape as a planar shape as illustrated in FIG. 10, and may be arranged, for example, in a honeycomb structure. Alternatively, the unit pixels P may each have, for example, a substantially circular shape as a planar shape as illustrated in FIG. 11, and may be arranged, for example, in a matrix. Accordingly, it is possible to enhance field uniformity in the high electric field region while maximizing the area of the unit pixels P similarly to the case where the planar shape of the unit pixel P is the substantially regular hexagonal shape. Therefore, in addition to the effects brought by the above-mentioned first embodiment, it is possible to further increase PDE.

### 2-2. Second Modification Example

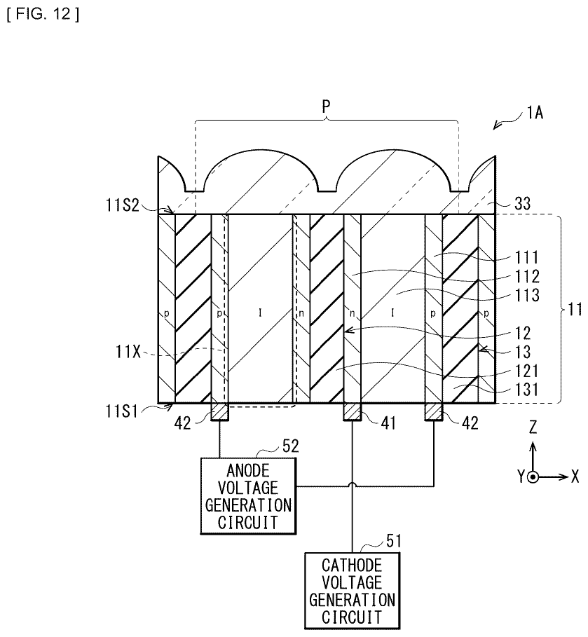

FIG. 12 schematically illustrates an example of a cross-sectional configuration of a photodetection device (a photodetection device 1A) according to a second modification example of the present disclosure. The photodetection device 1A is applied to the distance image sensor (the distance image apparatus 1000) that measures a distance using the ToF method, the image sensor, and the like similarly to, for example, the above-mentioned first embodiment.

In the above-mentioned first embodiment, the description has been given of the example in which one microlens 31 is provided in each unit pixel P, but the configuration is not limited thereto. For example, the microlens 31 having a ring shape may be provided in the unit pixel P as illustrated in FIG. 12.

This enables increase of an aperture ratio of the unit pixel P while preventing condensation of light into the middle of the pixel provided with the first trench 12. Therefore, in addition to the effects brought by the above-mentioned first embodiment, it is possible to further increase the PDE, while preventing flare caused by reflection in the first trench 12.

### 2-3. Third Modification Example

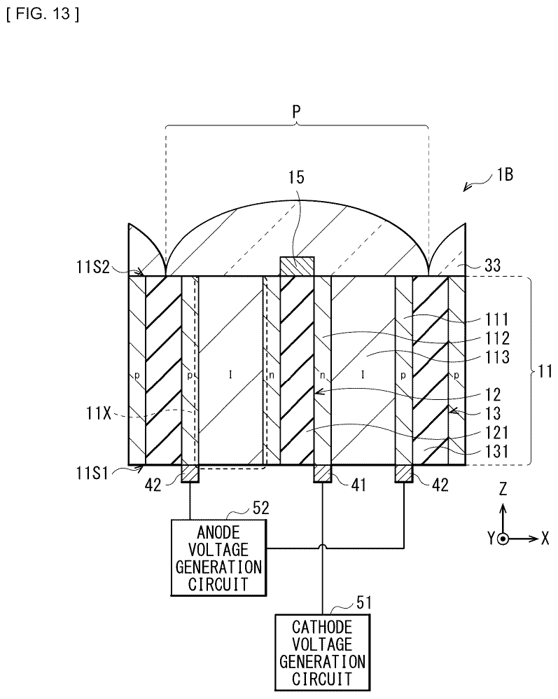

FIG. 13 schematically illustrates an example of a cross-sectional configuration of a photodetection device (a photodetection device 1B) according to a third modification example of the present disclosure. The photodetection device 1B is applied to the distance image sensor (the distance image apparatus 1000) that measures a distance using the ToF method, the image sensor, and the like similarly to, for example, the above-mentioned first embodiment.

A low refractive index film 15 having a refractive index lower than that of the microlens 31 may be provided above the first trench 12 on the second surface 11S2 side of the semiconductor substrate 11.

This enables increase of an aperture ratio of the unit pixel P while preventing condensation of light into the middle of the pixel provided with the first trench 12. Therefore, in addition to the effects brought by the above-mentioned first embodiment, it is possible to further increase PDE, while preventing flare caused by reflection in the first trench 12.

### 2-4. Fourth Modification Example

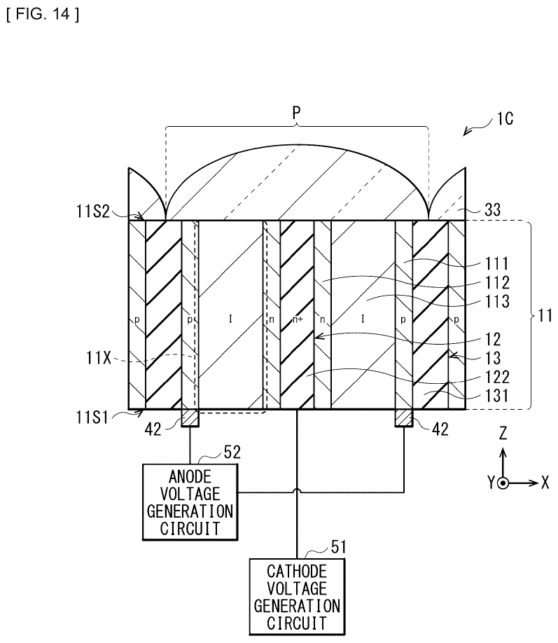

FIG. 14 schematically illustrates an example of a cross-sectional configuration of a photodetection device (a photodetection device 1C) according to a fourth modification example of the present disclosure. The photodetection device 1C is applied to the distance image sensor (the distance image apparatus 1000) that measures a distance using the ToF method, the image sensor, and the like similarly to, for example, the above-mentioned first embodiment.

In the above-mentioned first embodiment, the description has been given of the example in which the oxide film 121 is embedded in the first trench 12, but the configuration is not limited thereto. For example, polysilicon 122 doped with n-type impurities at a concentration higher than that of the N-type semiconductor layer 112 and made conductive may be embedded in the first trench 12.

Furthermore, for example, the cathode voltage generation circuit 51 may be coupled to the polysilicon 122 to apply, for example, a positive voltage to the polysilicon 122. This enables addition of a function as the cathode to the polysilicon 122.

This allows potentials of the N-type semiconductor layer 112 to be uniform in a Z-axis direction. Therefore, in addition to the effects brought by the above-mentioned first embodiment, it is possible to further increase field uniformity of the avalanche multiplication region 11X.

### 2-5. Fifth Modification Example

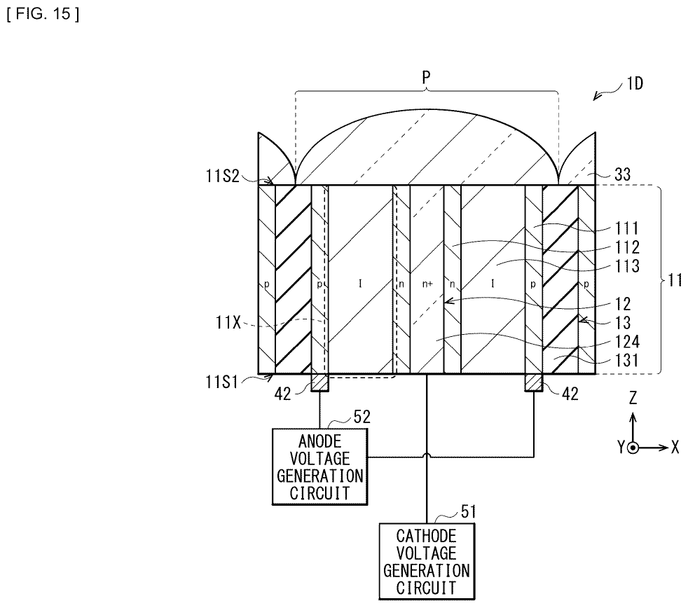

FIG. 15 schematically illustrates an example of a cross-sectional configuration of a photodetection device (a photodetection device 1D) according to a fifth modification example of the present disclosure. The photodetection device 1D is applied to the distance image sensor (the distance image apparatus 1000) that measures a distance using the ToF method, the image sensor, and the like similarly to, for example, the above-mentioned first embodiment.

In the above-mentioned first embodiment, the description has been given of the example in which the oxide film 121 is embedded in the first trench 12, but the configuration is not limited thereto. For example, a transparent electrode 124 including an electrically conductive material having light transparency may be embedded in the first trench 12. For example, the cathode voltage generation circuit 51 may be coupled to the transparent electrode 124.

This allows potentials of the N-type semiconductor layer 112 to be uniform in the Z-axis direction, similarly to the above-mentioned fourth modification example. Therefore, in addition to the effects brought by the above-mentioned first embodiment, it is possible to further increase field uniformity of the avalanche multiplication region 11X. Additionally, it is possible to suppress reflection of light condensed in the first trench 12 in the middle of the pixel by the microlens 31 in comparison with the photodetection device 1 according to the above-mentioned embodiment.

### 2-6. Sixth Modification Example

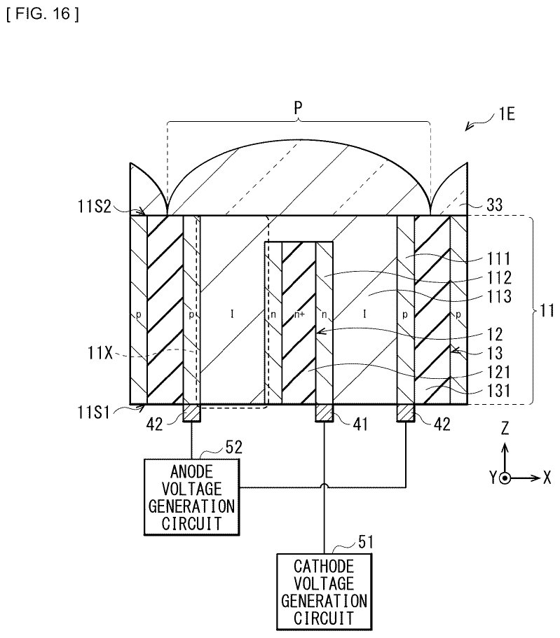

FIG. 16 schematically illustrates an example of a cross-sectional configuration of a photodetection device (a photodetection device 1E) according to a sixth modification example of the present disclosure. The photodetection device 1E is applied to the distance image sensor (the distance image apparatus 1000) that measures a distance using the ToF method, the image sensor, and the like similarly to, for example, the above-mentioned first embodiment.

In the above-mentioned first embodiment, the description has been given of the example in which the first trench 12 penetrates the semiconductor substrate 11, but the configuration is not limited thereto. The first trench 12 only has to extend from the first surface 11S1 side of the semiconductor substrate 11 to near the second surface 11S2 of the semiconductor substrate 11, or may have a bottom surface inside the semiconductor substrate 11 as illustrated in FIG. 16.

As a result, since the microlens 31 prevents the first trench 12 from being directly exposed to light condensed in the middle of the pixel, it is possible to suppress reflection of light in the first trench 12. Therefore, it is possible to prevent occurrence of flare while increasing the aperture ratio of the unit pixel P.

### 2-7. Seventh Modification Example

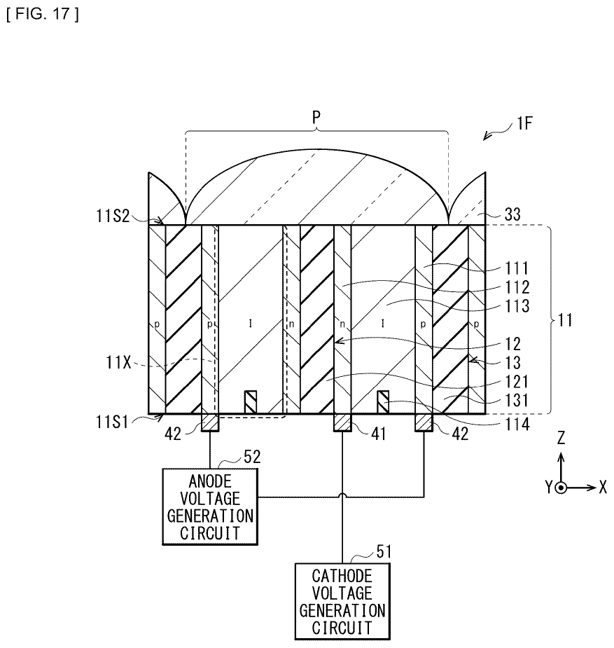

FIG. 17 schematically illustrates an example of a cross-sectional configuration of a photodetection device (a photodetection device 1F) according to a seventh modification example of the present disclosure. The photodetection device 1F is applied to the distance image sensor (the distance image apparatus 1000) that measures a distance using the ToF method, the image sensor, and the like similarly to, for example, the above-mentioned first embodiment.

A shallow trench isolation (STI) 114 may be provided between the first trench 12 and the second trench 13 in the first surface 11S1 of the semiconductor substrate 11 as illustrated in FIG. 17.

This can suppress occurrence of edge breakdown between electrodes and occurrence of leak current.

### 2. Second Embodiment

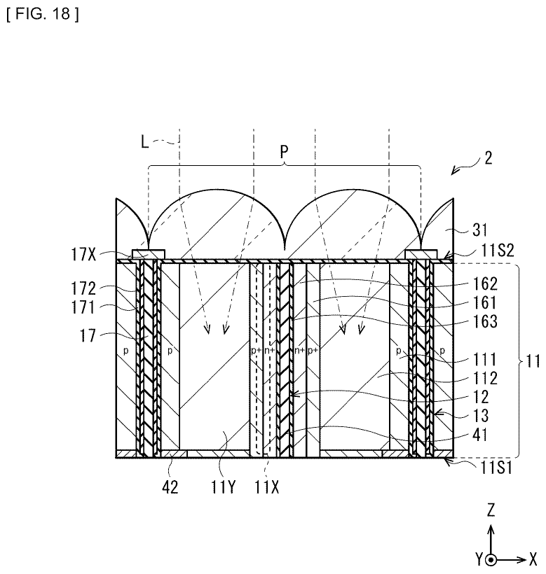

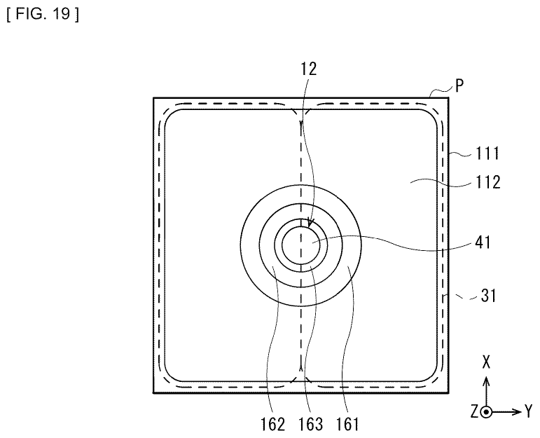

FIG. 18 schematically illustrates an example of a cross-sectional configuration of a main section of a photodetection device (a photodetection device 2) according to a second embodiment of the present disclosure. FIG. 19 schematically illustrates an example of a planar configuration of a unit pixel P constituting the photodetection device 2 illustrated in FIG. 18. The photodetection device 2 is applied to, for example, the distance image sensor (the distance image apparatus 1000, which will be described later with reference to FIG. 34) that measures a distance using the ToF method, the image sensor, and the like.

### (2-1. Configuration of Photodetection Device)

The photodetection device 2 has a configuration similar to that of the photodetection device 1 according to the above-described first embodiment. The photodetection device 2 includes, for example, the pixel array section 100A in which the plurality of unit pixels P is arranged in the array in the row and column directions. The photodetection device 2 includes the bias voltage application unit 110 in addition to the pixel array section 100A. The bias voltage application unit 110 applies a bias voltage to each unit pixel P in the pixel array section 100A. In the present embodiment, a description will be given of a case of reading out electrons as a signal charge.

The photodetection device 2 is, for example, a so-called back-illuminated photodetection device in which the logic substrate 20 is laminated on the surface (first surface 11S1) side of the semiconductor substrate 11 constituting the sensor substrate 10, and that receives light from the back surface side of the sensor substrate 10 (for example, the back surface (second surface 11S2) of the semiconductor substrate 11 constituting the sensor substrate 10).

As described above, the plurality of unit pixels P is arranged in the array in the row and column directions. In the semiconductor substrate 11, a first trench 12 penetrating between the first surface 11S1 and second surface 11S2 of the semiconductor substrate 11 is provided in the approximate middle of each of the plurality of unit pixels P arranged in the array. In the semiconductor substrate 11, the second trench 13 is further provided around the unit pixel P. The second trench 13 penetrates between the first surface 11S1 and second surface 11S2 of the semiconductor substrate 11 similarly to the first trench 12, and electrically separates adjacent unit pixel P. In the present embodiment, an N-type semiconductor layer 162 is provided along the side wall of the first trench 12, and a P-type semiconductor layer 161 is provided with the N-type semiconductor layer 162 interposed between the side wall of the first trench 12 and the P-type semiconductor layer 161. When a reverse bias voltage that is higher than a breakdown voltage is applied, the high electric field region in which avalanche multiplication occurs (avalanche multiplication region 11X) is formed between the P-type semiconductor layer 161 and the N-type semiconductor layer 162 throughout between the first surface 11S1 and the second surface 11S2.

Note that “p” and “n” in the drawing respectively represent the P-type semiconductor layer and the N-type semiconductor layer. Furthermore, “+” after “p” represents an impurity concentration in the P-type semiconductor layer. Similarly, “+” after “n” represents an impurity concentration in the N-type semiconductor layer. Here, the larger the number of “+”, the higher the impurity concentration. Similar things apply to the subsequent drawings.

The sensor substrate 10 includes, for example, the semiconductor substrate 11 and the multilayer wiring layer 19. The semiconductor substrate 11 includes a silicon substrate. The semiconductor substrate 11 has the first surface 11S1 and the second surface 11S2 that are opposed to each other. The semiconductor substrate 11 includes a p well (p) that is common to the plurality of unit pixels P. The N-type semiconductor layer 112 constituting a photoelectric conversion region 11Y is provided in the semiconductor substrate 11 on the unit pixel P-by-unit pixel P basis. In the N-type semiconductor layer 112, an impurity concentration is controlled to be an n-type, The P-type semiconductor layer 111 in which an impurity concentration is higher than that of the p well is provided along the side wall of the second trench 13. The P-type semiconductor layer 111 further extends to the first surface 11S1 of the semiconductor substrate 11.

The light-receiving element 1X includes the multiplication region in which carriers are avalanche-multiplied by the high electric field region (avalanche multiplication region 11X), and is, for example, a SPAD element that forms the avalanche multiplication region 11X by application of a high negative voltage to the cathode 41 and that enables avalanche multiplication of electrons generated by incidence of one photon.

The photoelectric conversion region 11Y is, for example, embedded and formed in the semiconductor substrate 11, absorbs light incident from the second surface 11S2 side of the semiconductor substrate 11, and has a photoelectric conversion function of generating carriers according to an amount of the received light. The photoelectric conversion region 11Y includes the N-type semiconductor layer 112 in which the impurity concentration is controlled to be the n-type as described above, and carriers (electrons) generated in the photoelectric conversion region 11Y are transferred to the avalanche multiplication region 11X by a potential gradient.

In the light-receiving element 1X, the avalanche multiplication region 11X is formed in a junction portion between the P-type semiconductor layer 161 and the N-type semiconductor layer 162. The avalanche multiplication region 11X is the high electric field region (depletion layer) formed between the P-type semiconductor layer 161 and the N-type semiconductor layer 162 by application of a reverse bias voltage that is higher than a breakdown voltage to the cathode 41 and the anode 42. In the avalanche multiplication region 11X, electrons (e−) generated by one photon incident on the light-receiving element 1X are multiplied.

As the anode electrically coupled to the P-type semiconductor layer 111, a contact layer including a p-type semiconductor region (p++), as the anode 42 electrically coupled to the P-type semiconductor layer 111, is further provided in the first surface 11S1 of the semiconductor substrate 11.

For example, a fixed charge film 171 is arranged in the second surface 11S2 of the semiconductor substrate 11.

As the cathode 41, for example, polysilicon, which has been made conductive, is embedded in the first trench 12.

The second trench 13 electrically separates adjacent unit pixels P, and is, for example, provided in a grid-like shape in the pixel array section 100A so as to surround each of the plurality of unit pixels P in a plan view. The second trench 13 extends between the first surface 11S1 and second surface 11S2 of the semiconductor substrate 11, and, for example, penetrates the semiconductor substrate 11. The side wall of the second trench 13 is, for example, covered with the fixed charge film 171 extending from the second surface 11S2 of the semiconductor substrate 11 and an oxide film 172 having an insulation property. For example, a light-shielding film 17 is embedded in the second trench 13 covered with the fixed charge film 171 and the oxide film 172.

The multilayer wiring layer 14 is provided on the first surface 11S1 side of the semiconductor substrate 11, similarly to the photodetection device 1 according to the above-mentioned first embodiment, and the logic substrate 20 is further attached to the first surface 11S1 side of the semiconductor substrate 11.

For example, one or more microlenses 31 are provided on the light-receiving surface (second surface 11S2) side of the semiconductor substrate 11, for example, on the unit pixel P-by-unit pixel P basis. The protective layer 32 and the color filter 33 may be further provided between the second surface 11S2 of the semiconductor substrate 11 and the microlens 31.

The microlens 31 condenses light incident from above the microlens 31 into the light-receiving element 1X, and is formed using, for example, oxide silicon (SiOₓ) or the like.

In the present embodiment, the photoelectric conversion region 11Y is provided at a position where the largest amount of light L having penetrated the microlens 31 is condensed, and the first trench 12 and the second trench 13 are provided at a position where the microlens 31 has the smallest thickness. For example, in the photodetection device 2, two microlenses 31 are provided on each unit pixel P as illustrated in FIG. 19. The first trench 12 is, for example, provided below a boundary between the two adjacent microlenses 31 in the unit pixel P in a plan view. The second trench 13 is provided, for example, along a boundary between microlenses 31 in adjacent unit pixels P.

### (2-1. First Method of Manufacturing Photodetection Device)

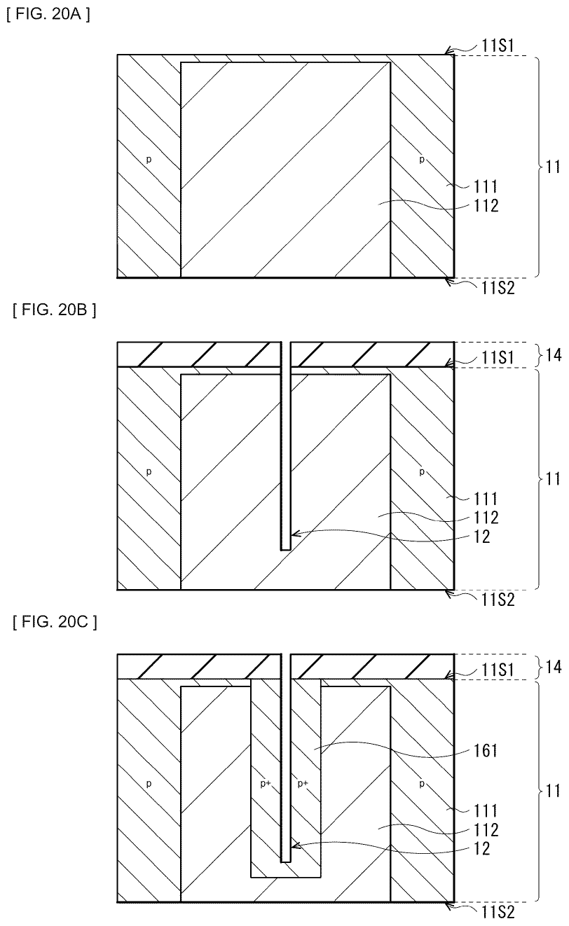

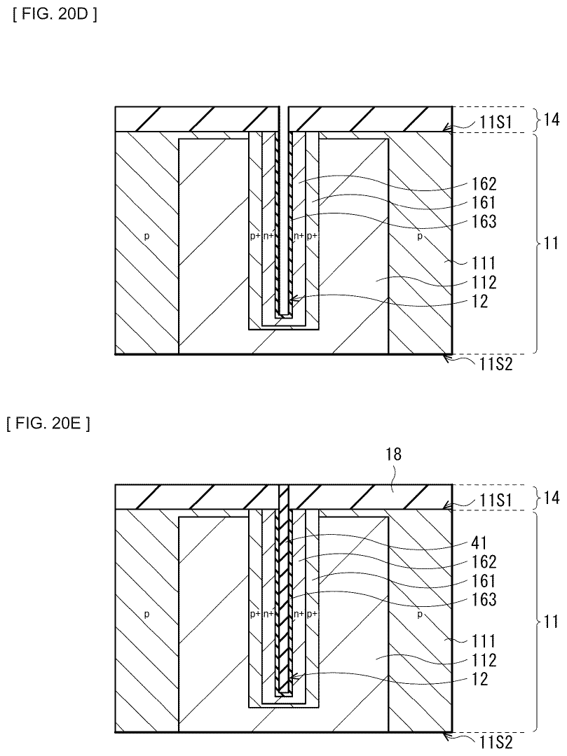

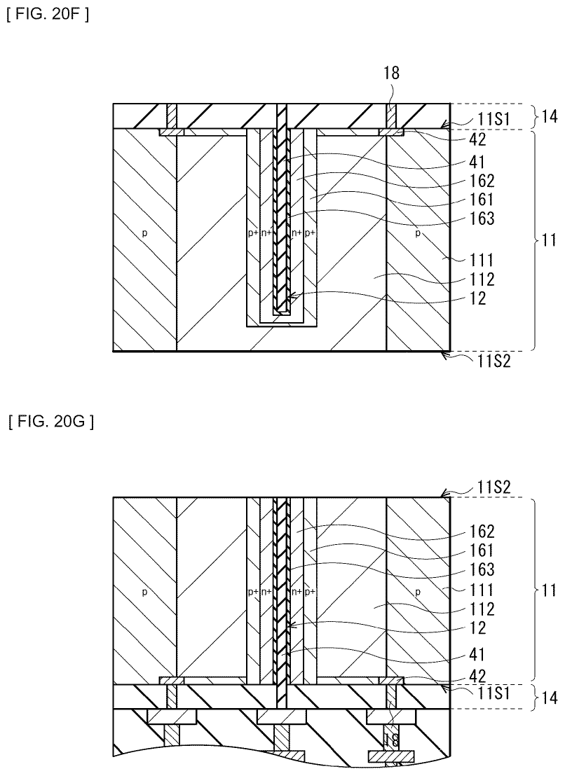

For example, it is possible to manufacture the sensor substrate 10 as follows. First, as illustrated in FIG. 20A, the P-type semiconductor layer 111 is formed in a predetermined region of the semiconductor substrate 11 by ion implantation. Specifically, for example, as illustrated in FIG. 18, the second trench 13 is formed between the adjacent unit pixels P, the P-type semiconductor layer 111 is formed by ion implantation or solid-phase diffusion, and thereafter the oxide film 131 is embedded in the second trench 13. Subsequently, as illustrated in FIG. 20B, a resist film having a predetermined pattern is formed on the first surface 11S1 of the semiconductor substrate 11, and the first trench 12 having a predetermined depth is formed.

Subsequently, as illustrated in FIG. 20C, doping with highly concentrated p-type impurities is performed using solid-phase diffusion from the first trench 12, and the P-type semiconductor layer 161 is formed on the side wall and bottom surface of the first trench 12 is formed. Subsequently, as illustrated in FIG. 20D, doping with highly concentrated n-type impurities is performed using solid-phase diffusion from the first trench 12, and N-type semiconductor layers 162 and 163 are sequentially formed on the side wall and bottom surface of the first trench 12. Subsequently, as illustrated in FIG. 20E, polysilicon is embedded in the first trench 12 to form the cathode 41.

Subsequently, as illustrated in FIG. 20F, the anode 42 is formed at a predetermined position of the first surface 11S1 of the semiconductor substrate 11, and the multilayer wiring layer 14 including wiring for pulling out the anode and the like is further formed on the first surface 11S1.

Thereafter, as illustrated in FIG. 20G, the logic substrate 20, which is separately produced, is attached onto the multilayer wiring layer 14. At this time, Cu—Cu bonding is performed between the plurality of pad electrodes 193 exposed on the bonding surface (surface 19S1) of the multilayer wiring layer 19 and the plurality of pad sections 217 exposed on the bonding surface (surface 22S) of the multilayer wiring layer 22 on the logic substrate 20 side. Subsequently, in hot water illustrated in FIG. 20G, for example, the first surface 11S1 of the semiconductor substrate 11 is polished by, for example, a grinder, CMP, or LEP, to expose the bottom surface of the first trench 12 and the bottom surface of the second trench 13, and the first surface 11S1 is planarized. Thereafter, for example, after the first surface 11S1 of the semiconductor substrate 11 is planarized by, for example, CMP, the microlens 31 and the like are formed. Accordingly, the photodetection device 2 illustrated in FIG. 18 is completed.

### (2-2. Second Method of Manufacturing Photodetection Device)

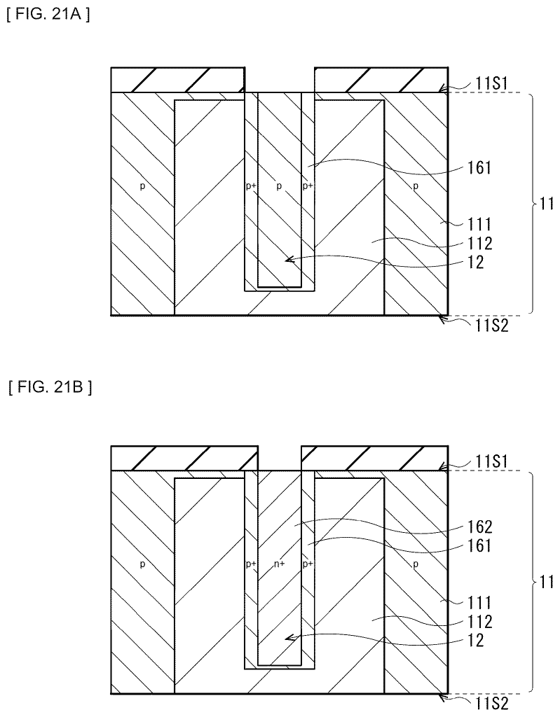

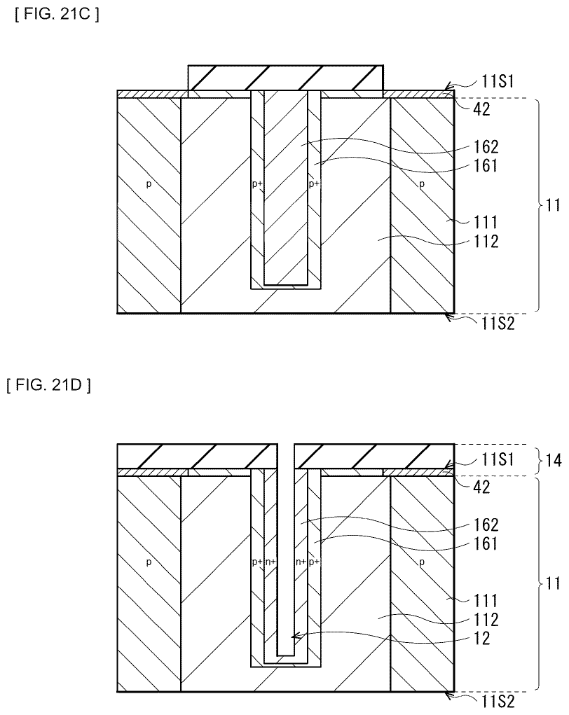

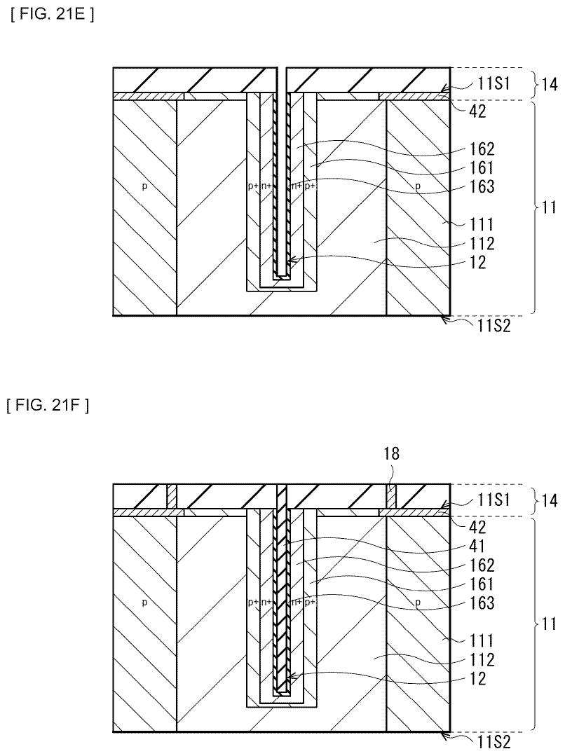

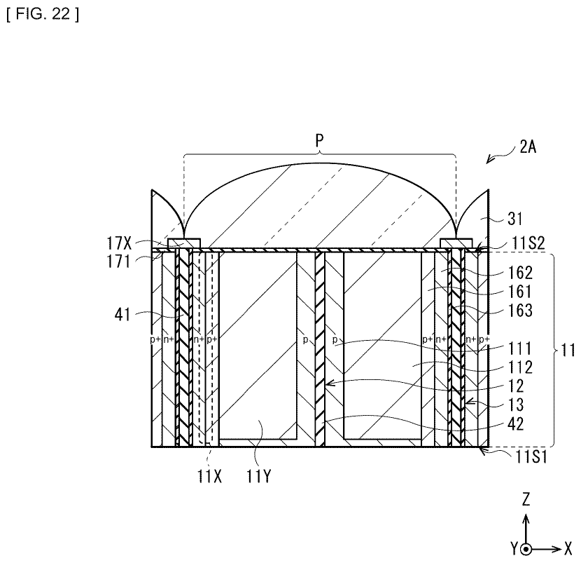

For example, it is possible to manufacture the sensor substrate 10 as follows. First, similarly to the above-mentioned first manufacturing method, the P-type semiconductor layer 111 is formed in a predetermined region of the semiconductor substrate 11 by ion implantation, and thereafter doping with the highly concentrated p-type impurities is performed by ion implantation to form the P-type semiconductor layer 161 in a predetermined region of the semiconductor substrate 11 as illustrated in FIG. 21A.

Subsequently, as illustrated in FIG. 21B, the resist film having the predetermined pattern is formed on the first surface 11S1 of the semiconductor substrate 11, and doping with highly concentrated n-type impurities is performed by ion implantation to form the N-type semiconductor layer 162. Subsequently, as illustrated in FIG. 21C, the resist film having the predetermined pattern is formed on the first surface 11S1 of the semiconductor substrate 11, and the anode 42 is formed at the predetermined position by ion implantation. Subsequently, as illustrated in FIG. 21D, the resist film having the predetermined pattern is formed on the first surface 11S1 of the semiconductor substrate 11, and the first trench 12 having the predetermined depth is formed.

Subsequently, as illustrated in FIG. 21E, doping with highly concentrated n-type impurities by ion implantation using solid-phase diffusion, and the N-type semiconductor layer 163 is formed on the side surface and bottom surface of the first trench 12. Subsequently, as illustrated in FIG. 21F, polysilicon is embedded in the first trench 12 to form the cathode 41. Thereafter, similarly to the above-mentioned first manufacturing method, the multilayer wiring layer 14 is formed, and thereafter the logic substrate 20, which is separately produced, is attached. Subsequently, the first surface 11S1 of the semiconductor substrate 11 is polished by, for example, a grinder, CMP, or LEP, to expose the bottom surface of the first trench 12 and the bottom surface of the second trench 13, and the first surface 11S1 is planarized. Thereafter, for example, after the first surface 11S1 of the semiconductor substrate 11 is planarized by, for example, CMP, the microlens 31 and the like are formed. Accordingly, the photodetection device 2 illustrated in FIG. 18 is completed.

### (2-3. Workings and Effects)

In the photodetection device 2 according to the present embodiment, the photoelectric conversion region 11Y is provided at the position where the largest amount of light L having penetrated the microlens 31 is condensed, the first trench 12 and the second trench 13 are provided at the respective positions where the microlens 31 has the smallest thickness, and the N-type semiconductor layer 162 and the P-type semiconductor layer 161 are provided along the side wall of the first trench 12. When a reverse bias voltage that is higher than a breakdown voltage is applied, the high electric field region in which avalanche multiplication occurs (the avalanche multiplication region 11X) is formed between the P-type semiconductor layer 161 and the N-type semiconductor layer 162 throughout between the first surface 11S1 and the second surface 11S2. A description about this will be given below.

One of characteristics that the SPAD element is requested to have is jitter. The jitter generally represents fluctuations in timing of a digital signal. In the SPAD element, the jitter represents fluctuations in timing of a detection signal that has undergone reception of light, photoelectric conversion, multiplication, and detection. Since photoelectric conversion using detected light occurs in the whole pixel, there occurs a difference in time taken to transfer electrons to the avalanche multiplication region in which the high electric field is provided depending on generation positions of carriers (for example, electrons) generated by photoelectric conversion. For example, in the back-illuminated SPAD structure, the closer a carrier to a light-receiving surface side, the longer transfer time taken to transfer the carrier to the multiplication region. A difference in the transfer time appears as jitter characteristics.

To address this, in the present embodiment, the photoelectric conversion region 11Y is provided at the position where the largest amount of light L having penetrated the microlens 31 is condensed, the first trench 12 and the second trench 13 are provide at the respective positions where the microlens 31 has the smallest thickness, and the N-type semiconductor layer 162 and the P-type semiconductor layer 161 are provided along the side wall of the first trench 12. This uniformizes a transfer path from the photoelectric conversion region 11Y to the avalanche multiplication region 11X and the cathode 41, shortens a distance of the transfer path, and thereby reduces variations in timing of arrival at the cathode 41.

This allows the photodetection device 2 according to the present embodiment to improve the jitter characteristics.

### 4. Modification Examples

### 4-1. Eighth Modification Example

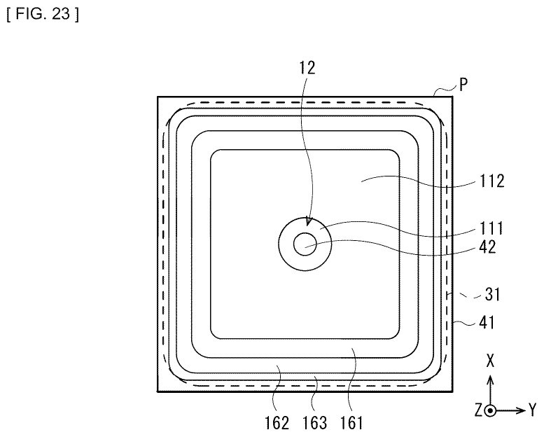

FIG. 22 schematically illustrates an example of a cross-sectional configuration of a photodetection device (a photodetection device 2A) according to an eighth modification example of the present disclosure. FIG. 23 schematically illustrates an example of the planar configuration of the unit pixel P constituting the photodetection device 2A illustrated in FIG. 22. The photodetection device 2A is applied to the distance image sensor (the distance image apparatus 1000) that measures a distance using the ToF method, the image sensor, and the like similarly to, for example, the above-mentioned second embodiment.

In the above-mentioned second embodiment, the description has been given of the example in which the two microlenses 31 are provided in the unit pixel P and the N-type semiconductor layer 162 and the P-type semiconductor layer 161 are provided along the side wall of the first trench 12, but the configuration is not limited thereto. For example, as illustrated in FIG. 22, a configuration may be adopted in which one microlens 31 is provided in the unit pixel P, the anode 42 and the cathode 41 are respectively embedded in the first trench 12 and the second trench 13, and the N-type semiconductor layer 162 and the P-type semiconductor layer 161 are provided along the side wall of the second trench 13.

This enables further increase of the PDE in comparison with the above-mentioned second embodiment.

### 4-2. Ninth Modification Example

In the above-mentioned second embodiment, the description has been given of the example in which the first trench 12 is provided in the approximate middle of the unit pixel P, and the N-type semiconductor layer 162 and the P-type semiconductor layer 161 are provided along the side wall of the first trench 12, but the configuration is not limited thereto.

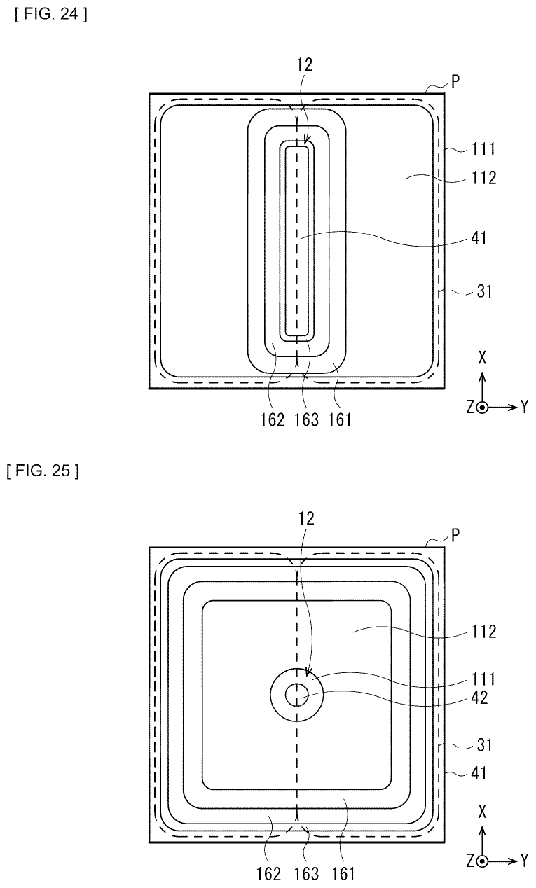

The first trench 12 may extend in a Y-axis direction along the boundary between the two adjacent microlenses 31 in the approximate middle of the unit pixel P, as illustrated in, for example, FIG. 24.

This enables improvement of the jitter characteristics in comparison with the above-mentioned second embodiment.

### 4-3. Tenth Modification Example

As illustrated in FIG. 25, a configuration combining the second embodiment and the eight modification example described above may be adopted in which two microlenses 31 are provided in the unit pixel P, the anode 42 is provided in the first trench 12 provided in the approximate middle of the unit pixel P, the light-shielding film 17 embedded in the second trench 13 serves as the cathode 41, and the N-type semiconductor layer 162 and the P-type semiconductor layer 161 are provided along the side wall of the second trench 13.

### 4-4. Eleventh Modification Example

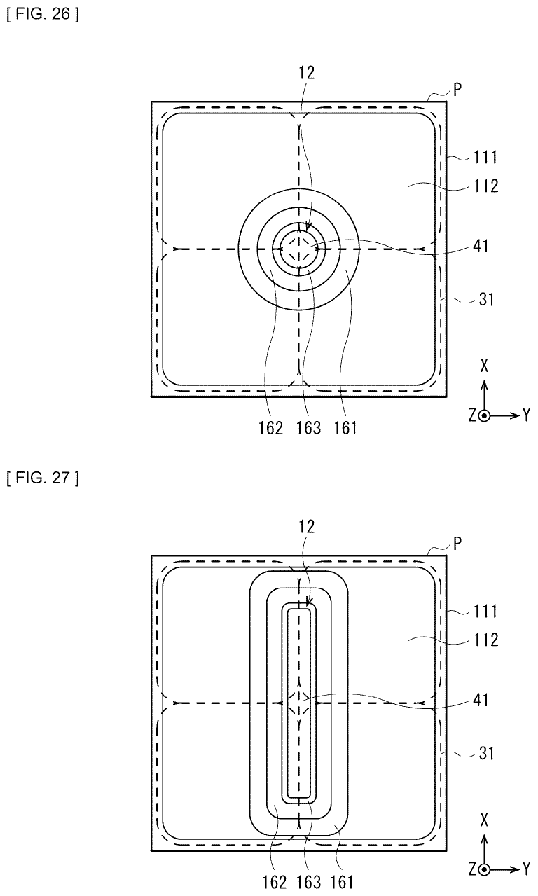

In the above-mentioned second embodiment, the description has been given of the example in which the two microlenses 31 are provided in the unit pixel P, but, for example, four microlenses 31 may be provided in the unit pixel P. In this case, as illustrated in FIG. 26, the first trench 12 may be arranged in the approximate middle, and the N-type semiconductor layer 162 and the P-type semiconductor layer 161 may be provided along the side wall of the first trench 12.

### 4-5. Twelfth Modification Example

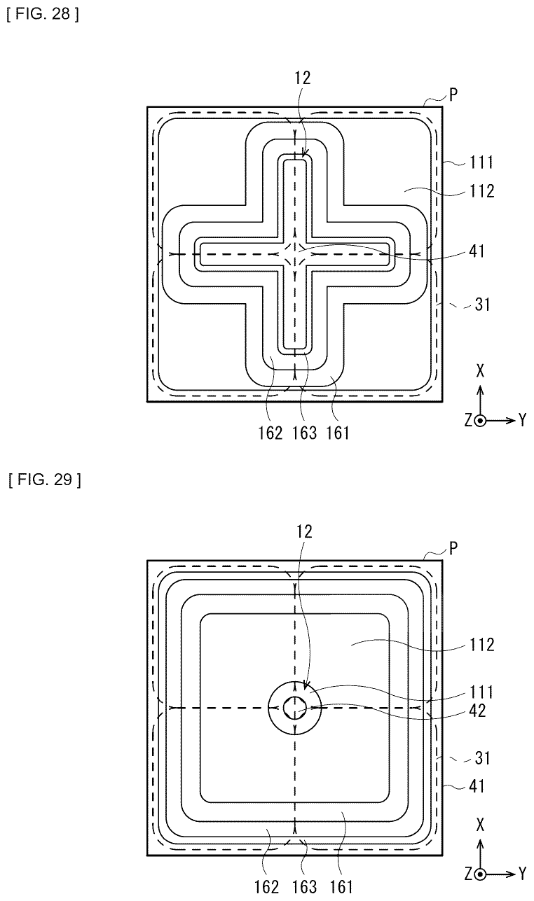

In the above-mentioned second embodiment, the description has been given of the example in which the two microlenses 31 are provided in the unit pixel P, but, for example, four microlenses 31 may be provided in the unit pixel P. In this case, as illustrated in FIG. 27, a configuration in combination with, for example, the ninth modification example, may be adopted in which the first trench 12 extends, for example, in the Y-axis direction in the approximate middle of the unit pixel P.

This enables further increase of the PDE in comparison with the above-mentioned eleventh modification example.

### 4-6. Thirteenth Modification Example

In the above-mentioned second embodiment, the description has been given of the example in which the two microlenses 31 are provided in the unit pixel P, but, for example, four microlenses 31 may be provided in the unit pixel P. In this case, the first trench 12 may extend in, for example, a cross shape in the X- and Y-axis directions along boundaries between four adjacent microlenses in the unit pixel P, as illustrated in FIG. 28.

This enables further increase of the PDE in comparison with the above-mentioned eleventh modification example.

### 4-7. Fourteenth Modification Example

As illustrated in FIG. 29, the first modification example and the eleventh modification example may be combined with each other.

### 4-8. Fifteenth Modification Example

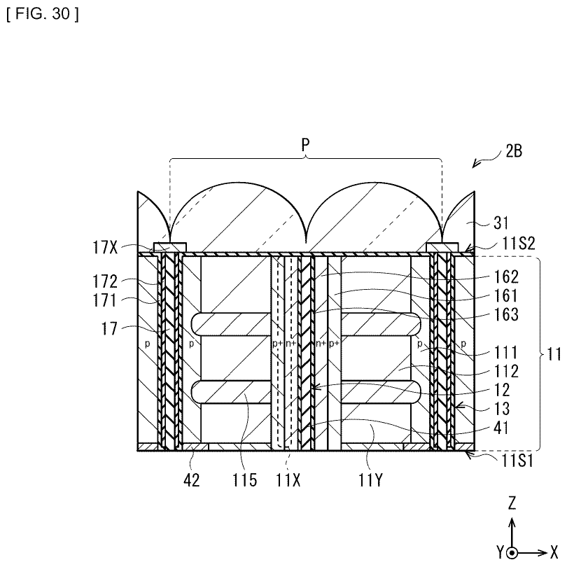

FIG. 30 schematically illustrates an example of a cross-sectional configuration of a photodetection device (a photodetection device 2B) according to a fifteenth modification example of the present disclosure. The photodetection device 2B is be applied to the distance image sensor (the distance image apparatus 1000) that measures a distance using the ToF method, the image sensor, and the like similarly to, for example, the above-mentioned second embodiment.

For example, an impurity layer 115 of a p-type or an n-type extending from the approximate middle of the unit pixel P toward the outer periphery may be further provided inside the semiconductor substrate 11.

This prevents transfer of carriers in the Z-axis direction, and enables further improvement of the jitter characteristics in comparison with the above-mentioned second embodiment.

### 4-9. Sixteenth Modification Example

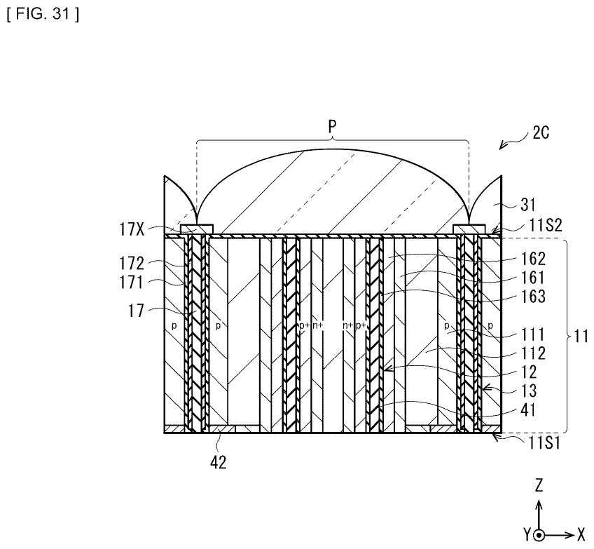

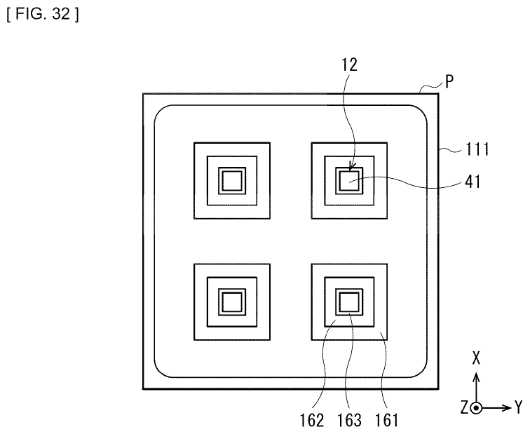

FIG. 31 schematically illustrates an example of a cross-sectional configuration of a photodetection device (a photodetection device 2C) according to a sixteenth modification example of the present disclosure. FIG. 32 schematically illustrates an example of a planar configuration of the photodetection device 2C illustrated in FIG. 31. The photodetection device 2C is applied to the distance image sensor (the distance image apparatus 1000) that measures a distance using the ToF method, the image sensor, and the like similarly to, for example, the above-mentioned second embodiment.

In the above-mentioned first embodiment or the like, the description has been given of the example in which the first trench 12 is provided in the approximate middle of the unit pixel P, but the configuration is not limited thereto. For example, as illustrated in FIG. 31, a plurality of first trenches 12 may be provided inside the unit pixel P.

This further shortens the distance of the transfer path from the photoelectric conversion region 11Y to the avalanche multiplication region 11X and the cathode 41, and further reduces variations in timing of arrival at the cathode 41, in comparison with the above-mentioned second embodiment.

### 4-10. Seventeenth Modification Example

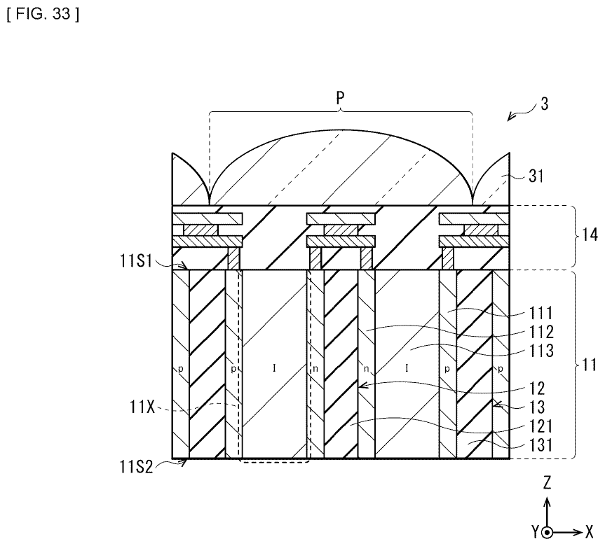

FIG. 33 schematically illustrates an example of a cross-sectional configuration of a photodetection device (a photodetection device 3) according to a seventeenth modification example of the present disclosure. In the above-mentioned first and second embodiments, the description has been given of the present technique using the back-illuminated photodetection device, but the present technique is not limited thereto. In the present technique, as illustrated in FIG. 33, the multilayer wiring layer 14 may be provided on the light-receiving surface side.

### 5. Application Examples

FIG. 34 illustrates an example of a schematic configuration of the distance image apparatus 1000 as an electronic apparatus including the photodetection apparatus (for example, the photodetection device 1) according to the first and second embodiments and the first to seventeenth modification examples described above. The distance image apparatus 1000 corresponds to one specific example of a “distance measuring apparatus” of the present disclosure.

The distance image apparatus 1000 includes, for example, a light source apparatus 1100, an optical system 1200, the photodetection device 1, an image processing circuit 1300, a monitor 1400, and a memory 1500.

The distance image apparatus 1000 receives light that is projected from the light source apparatus 1100 to an irradiation target 2000 and that is reflected on a surface of the irradiation target 2000 (modulating light or pulsed light). This allows the distance image apparatus 1000 to acquire a distance image in accordance with a distance to the irradiation target 2000.

The optical system 1200 includes one or more lenses, guides image light (incident light) from the irradiation target 2000 to the photodetection device 1, and forms an image on the light-receiving surface (sensor unit) of the photodetection device 1.

The image processing circuit 1300 performs image processing to construct a distance image on the basis of a distance signal supplied from the photodetection device 1. The distance image (image data) obtained by the image processing is supplied to and displayed on the monitor 1400 or supplied to and stored (recorded) in the memory 1500.

The application of the above-mentioned photodetection apparatus (for example, the photodetection device 1) to the distance image apparatus 1000 having such a configuration allows the distance image apparatus 1000 to calculate the distance to the irradiation target 2000 on the basis of only light-receiving signals from stable unit pixels P and generate a distance image with higher accuracy. That is, it is possible for the distance image apparatus 1000 to acquire a more precise distance image.

### 6. Applications

### (Application in Mobile Object)

It is possible to apply the technique of the present disclosure to various products. For example, the technique of the present disclosure may be implemented as an apparatus that is mounted on a mobile object of any type of an automobile, an electric automobile, a hybrid electric automobile, an autobicycle, a bicycle, a personal mobility, an airplane, a drone, a ship, a robot, a construction machine, an agricultural machine (tractor), and the like.

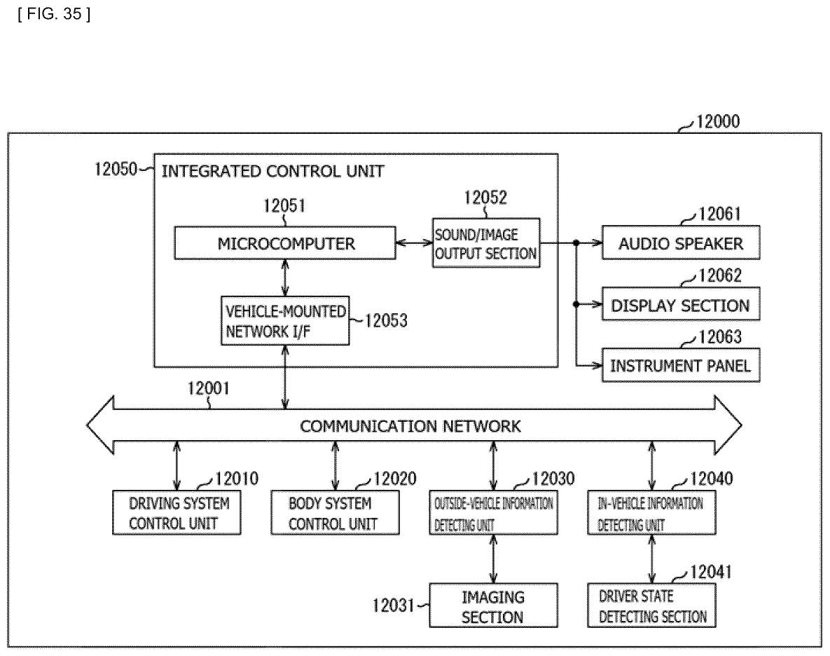

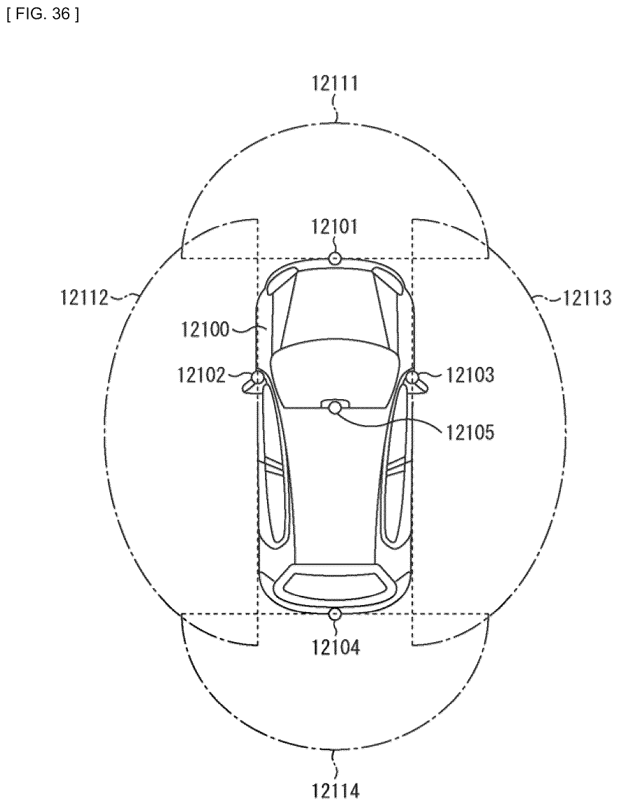

FIG. 35 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 35, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 35, an audio speaker 12061, a display section 12062, and an instrument panel 12063 are illustrated as the output device. The display section 12062 may, for example, include at least one of an on-board display and a head-up display.

FIG. 35 is a diagram depicting an example of the installation position of the imaging section 12031.

In FIG. 35, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 35 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

While the description has been given of the first and second embodiments, the first to seventeenth modification examples, the application examples, and the applications, the contents of the present disclosure are not limited to the above-mentioned embodiments and the like, and it is possible to make various modifications. For example, the photodetection apparatus according to the present disclosure does not necessarily include all of the components described in the above-mentioned embodiments and the like, and may include, conversely, another layer. For example, in a case where the photodetection device 1 detects light other than visible light (for example, near-infrared light (IR)), the color filter 33 may be omitted.

Additionally, a polarity of the semiconductor region constituting the photodetection device of the present disclosure may be reversed. Furthermore, in the photodetection device according to the present disclosure, a positive hole may serve as a signal charge.

Furthermore, the photodetection device of the present disclosure only has to be in a state where avalanche multiplication is caused by application of a reverse bias to between the anode and the cathode, potentials of the anode and the cathode are not limited.

While the description has been given of the example in which silicon is used as the semiconductor substrate 11 in the above-mentioned embodiments and the like, it is possible to use a compound semiconductor containing germanium (Ge) or silicon (Si) and germanium (Ge) (for example, silicon germanium (SiGe)) as the semiconductor substrate 11.

Note that the effects that have been described in the above-mentioned embodiments and the like are examples, and there may be another effect and still another effect may be included.

Note that the present disclosure may have the following configuration. According to the present technique having the following configuration, the first trench extending between the first surface and second surface of the semiconductor substrate is provided in the approximate middle of each of the plurality of pixels, and the first semiconductor layer of the first conductivity type and the second semiconductor layer of the second conductivity type that is opposite to the first conductivity type are provided in each of the plurality of pixels. The first semiconductor layer extends between the first surface and second surface of the semiconductor substrate. When a reverse bias voltage is applied, the high electric field region is formed between the first semiconductor layer and the second semiconductor layer throughout between the first surface and the second surface. This reduces variations in transfer time for transferring carriers generated by photoelectric conversion to the high electric field region in comparison with a typical photodetection device in which the high electric field region is formed in an in-plane direction of the semiconductor substrate. Therefore, it is possible to improve jitter characteristics.

(1)

A photodetection device including:
a semiconductor substrate having a first surface and a second surface that are opposed to each other and including a plurality of pixels arranged in an array in an in-plane direction;
a first trench extending between the first surface and the second surface in an approximate middle of each of the plurality of pixels;
a first semiconductor layer of a first conductivity type, the first semiconductor layer being provided in each of the plurality of pixels and extending between the first surface and the second surface; and
a second semiconductor layer of a second conductivity type that is opposite to the first conductivity type, the second semiconductor layer being provided in each of the plurality of pixels and extending between the first surface and the second surface, in which,
when a reverse bias voltage is applied, a high electric field region is formed between the first semiconductor layer and the second semiconductor layer throughout between the first surface and the second surface.
   (2)

The photodetection device according to (1), in which the semiconductor substrate further includes a second trench sectioning each of the plurality of pixels and penetrating between the first surface and the second surface.

(3)

The photodetection device according to (2), in which the first semiconductor layer is provided along a side surface of the second trench, and the second semiconductor layer is provided along a periphery of the first trench.

(4)

The photodetection device according to any one of (1) to (3), in which each of the plurality of pixels further includes an intrinsic semiconductor region between the first semiconductor layer and the second semiconductor layer, and forms a P-I-N structure.

(5)

The photodetection device according to any one of (1) to (4), in which an insulation material is embedded in the first trench.

(6)

The photodetection device according to any one of (1) to (4), in which polysilicon doped with an impurity of the first conductivity type is embedded in the first trench.

(7)

The photodetection device according to any one of (1) to (4), in which an electrically conductive material having light transparency is embedded in the first trench.

(8)

The photodetection device according to any one of (1) to (7), in which the first trench extends from the first surface to the second surface and has a bottom surface inside the semiconductor substrate.

(9)

The photodetection device according to any one of (1) to (8), further including a plurality of microlenses provided in each of the plurality of pixels on the second surface side of the semiconductor substrate.

(10)

The photodetection device according to (9), in which each of the plurality of microlenses has a ring shape.

(11)

The photodetection device according to (9) or (10), further including a low refractive index film having a refractive index that is lower than a refractive index of each of the plurality of microlenses, the low refractive index film being provided above the first trench on the second surface side of the semiconductor substrate.

(12)

The photodetection device according to any one of (2) to (11), further including one or a plurality of microlenses in each of the plurality of pixels on the second surface side of the semiconductor substrate, in which
each of the plurality of pixels includes a photoelectric conversion region at a position where a largest amount of light having penetrated the one or the plurality of microlenses is condensed, and
at least one of the first trench or the second trench is provided at a position where the one or the plurality of microlenses has a smallest thickness.
   (13)

The photodetection device according to (12), in which
each of the plurality of pixels includes the plurality of microlenses, and
an anode is embedded in the first trench and a cathode is embedded in the second trench.
   (14)

The photodetection device according to (12), in which
each of the plurality of pixels includes two or four of the microlenses, and
an anode is embedded in the first trench and a cathode is embedded in the second trench.
   (15)

The photodetection device according to (13), in which
the second semiconductor layer is provided along a side wall of the second trench, and
the first semiconductor layer is provided along a side wall of the second trench with the second semiconductor layer interposed between the side wall and the first semiconductor layer.
   (16)

The photodetection device according to (12), in which
each of the plurality of pixels includes two or four of the microlenses, and
a cathode is embedded in the first trench and an anode is embedded in the second trench.
   (17)

The photodetection device according to (16), in which
the second semiconductor layer is provided along a side wall of the first trench, and
the first semiconductor layer is provided along a side wall of the first trench with the second semiconductor layer interposed between the side wall and the first semiconductor layer.
   (18)

The photodetection device according to (16), in which the first trench extends from an approximate middle of the pixel toward an outer periphery along a boundary between adjacent ones of the microlenses where the microlenses has a smallest thickness.

(19)

The photodetection device according to any one of (1) to (18), in which
each of the plurality of pixels has a substantially square shape in a plan view, and
the plurality of pixels is arranged in a matrix.
   (20)

The photodetection device according to any one of (1) to (18), in which
each of the plurality of pixels has a substantially regular hexagonal shape in a plan view, and
the plurality of pixels is arranged in a honeycomb structure.
   (21)

The photodetection device according to any one of (1) to (18), in which
each of the plurality of pixels has a substantially circular shape in a plan view, and
the plurality of pixels is arranged in a matrix.
   (22)

The photodetection device according to any one of (1) to (18), in which
each of the plurality of pixels has a substantially circular shape in a plan view, and
the plurality of pixels is arranged in a honeycomb structure.

1. A photodetection device comprising:
a semiconductor substrate having a first surface and a second surface that are opposed to each other and including a plurality of pixels arranged in an array in an in-plane direction;
a first trench extending between the first surface and the second surface in an approximate middle of each of the plurality of pixels;
a first semiconductor layer of a first conductivity type, the first semiconductor layer being provided in each of the plurality of pixels and extending between the first surface and the second surface; and
a second semiconductor layer of a second conductivity type that is opposite to the first conductivity type, the second semiconductor layer being provided in each of the plurality of pixels and extending between the first surface and the second surface, wherein,
when a reverse bias voltage is applied, a high electric field region is formed between the first semiconductor layer and the second semiconductor layer throughout between the first surface and the second surface.

2. The photodetection device according to claim 1, wherein the semiconductor substrate further includes a second trench sectioning each of the plurality of pixels and penetrating between the first surface and the second surface.

3. The photodetection device according to claim 2, wherein
the first semiconductor layer is provided along a side surface of the second trench, and
the second semiconductor layer is provided along a periphery of the first trench.

4. The photodetection device according to claim 1, wherein
each of the plurality of pixels further includes an intrinsic semiconductor region between the first semiconductor layer and the second semiconductor layer, and forms a P-I-N structure.

5. The photodetection device according to claim 1, wherein an insulation material is embedded in the first trench.

6. The photodetection device according to claim 1, wherein polysilicon doped with an impurity of the first conductivity type is embedded in the first trench.

7. The photodetection device according to claim 1, wherein an electrically conductive material having light transparency is embedded in the first trench.

8. The photodetection device according to claim 1, wherein the first trench extends from the first surface to the second surface and has a bottom surface inside the semiconductor substrate.

9. The photodetection device according to claim 1, further comprising a plurality of microlenses provided in each of the plurality of pixels on the second surface side of the semiconductor substrate.

10. The photodetection device according to claim 9, wherein each of the plurality of microlenses has a ring shape.

11. The photodetection device according to claim 9, further comprising a low refractive index film having a refractive index that is lower than a refractive index of each of the plurality of microlenses, the low refractive index film being provided above the first trench on the second surface side of the semiconductor substrate.

12. The photodetection device according to claim 2, further comprising one or a plurality of microlenses in each of the plurality of pixels on the second surface side of the semiconductor substrate, wherein
each of the plurality of pixels includes a photoelectric conversion region at a position where a largest amount of light having penetrated the one or the plurality of microlenses is condensed, and
at least one of the first trench or the second trench is provided at a position where the one or the plurality of microlenses has a smallest thickness.

13. The photodetection device according to claim 12, wherein
each of the plurality of pixels includes the plurality of microlenses, and
an anode is embedded in the first trench and a cathode is embedded in the second trench.

14. The photodetection device according to claim 12, wherein
each of the plurality of pixels includes two or four of the microlenses, and
an anode is embedded in the first trench and a cathode is embedded in the second trench.

15. The photodetection device according to claim 13, wherein
the second semiconductor layer is provided along a side wall of the second trench, and
the first semiconductor layer is provided along a side wall of the second trench with the second semiconductor layer interposed between the side wall and the first semiconductor layer.

16. The photodetection device according to claim 12, wherein
each of the plurality of pixels includes two or four of the microlenses, and
a cathode is embedded in the first trench and an anode is embedded in the second trench.

17. The photodetection device according to claim 16, wherein
the second semiconductor layer is provided along a side wall of the first trench, and
the first semiconductor layer is provided along a side wall of the first trench with the second semiconductor layer interposed between the side wall and the first semiconductor layer.

18. The photodetection device according to claim 16, wherein the first trench extends from an approximate middle of the pixel toward an outer periphery along a boundary between adjacent ones of the microlenses where the microlenses has a smallest thickness.

19. The photodetection device according to claim 1, wherein
each of the plurality of pixels has a substantially square shape in a plan view, and
the plurality of pixels is arranged in a matrix.

20. The photodetection device according to claim 1, wherein
each of the plurality of pixels has a substantially regular hexagonal shape in a plan view, and
the plurality of pixels is arranged in a honeycomb structure.

21. The photodetection device according to claim 1, wherein
each of the plurality of pixels has a substantially circular shape in a plan view, and
the plurality of pixels is arranged in a matrix.

22. The photodetection device according to claim 1, wherein
each of the plurality of pixels has a substantially circular shape in a plan view, and
the plurality of pixels is arranged in a honeycomb structure.
